(19) United States
(12) Patent Application Publication
(10) Pub. No.: US 2024/0395914 A1
(43) Pub. Date: Nov. 28, 2024

(54) SEMICONDUCTOR DEVICE

(71) Applicant: FUJI ELECTRIC CO., LTD., Kanagawa (JP)

(72) Inventor: Koh YOSHIKAWA, Matsumoto-city (JP)

(21) Appl. No.: 18/657,788

(22) Filed: May 8, 2024

(30) Foreign Application Priority Data
May 24, 2023 (JP) 2023-085496
Mar. 11, 2024 (JP) 2024-037474

(51) Int. Cl. H01L 29/739; H01L 29/06; H01L 29/423; H01L 29/66

(52) U.S. Cl. CPC H01L 29/7397; H01L 29/0696; H01L 29/4236; H01L 29/66348

(57) ABSTRACT

Provided is a semiconductor device comprising a semiconductor substrate comprising: a gate trench portion having a longitudinal side in a first direction at the upper surface of the semiconductor substrate; an emitter region of the first conductivity type which is provided to be exposed on the upper surface in the semiconductor substrate, is in contact with the gate trench portion, and has a length in the first direction that is longer than a length in a second direction orthogonal to the first direction; a base region of a second conductivity type which is provided between the emitter region and the drift region and is in contact with the gate trench portion: an emitter electrode provided above the upper surface of the semiconductor substrate; and a resistance portion provided between the emitter region and the emitter electrode.

The contents of the following patent application(s) are incorporated herein by reference:

NO. 2023-085496 filed in JP on May 24, 2023

NO. 2024-037474 filed in JP on Mar. 11, 2024

### BACKGROUND

### 1. Technical Field

The present invention relates to a semiconductor device.

### 2. Related Art

In the prior art, there is known a technique for, in a semiconductor device such as an Insulated Gate Bipolar Transistor (IGBT), changing for example arrangement of emitter regions and adjusting characteristics (see Patent Documents 1 to 3, for example).

Patent Document 1: Japanese Patent Application Publication No. 2008-91491

Patent Document 2: Japanese Patent Application Publication No. H10-173170

Patent Document 3: Japanese Patent Application Publication No. H9-283755

### BRIEF DESCRIPTION OF THE DRAWINGS

FIG. 1 is a top view showing one example of a semiconductor device 100.

FIG. 2 is one example of an enlarged view of a region D in FIG. 1.

FIG. 3 illustrates one example of a cross section taken along a line a-a in FIG. 2.

FIG. 4 illustrates one example of a cross section taken along a line b-b in FIG. 2.

FIG. 5 illustrates one example of potential distributions of a polysilicon resistance portion 200, an emitter region 12, a base region 14, and a drift region 18 in a depth direction.

FIG. 6 is another example of the enlarged view of the region D in FIG. 1.

FIG. 7 is another example of the enlarged view of the region D in FIG. 1.

FIG. 8 illustrates one example of a cross section c-c in FIG. 7.

FIG. 9 is another example of the enlarged view of the region D in FIG. 1.

FIG. 10 illustrates one example of a cross section d-d in FIG. 9.

FIG. 11 is another example of the enlarged view of the region D in FIG. 1.

FIG. 12A illustrates one example of a cross section e-e in FIG. 11.

FIG. 12B is an enlarged view of the vicinity of a dummy trench portion 30 shown in FIG. 12A.

FIG. 12C is another example of the enlarged view of the vicinity of the dummy trench portion 30 shown in FIG. 12A.

FIG. 13 illustrates one example of a cross section f-f in FIG. 11.

FIG. 14 is an enlarged view of the vicinity of a polysilicon resistance portion 200.

FIG. 15 illustrates one example of an impurity concentration distribution of the polysilicon resistance portion 200 on a line g-g in FIG. 14.

FIG. 16 illustrates another example of a polysilicon resistance portion 200.

FIG. 17 illustrates some processes in a method for manufacturing a semiconductor device 100.

FIG. 18 illustrates another example of a method for manufacturing a semiconductor device 100.

FIG. 19 illustrates a relationship between an impurity concentration of a polysilicon resistance portion 200 and a saturation current flowing through a semiconductor device 100.

FIG. 20 illustrates relationships between an impurity concentration of a polysilicon resistance portion 200 and an ON voltage of a semiconductor device 100.

FIG. 21 is a cross-sectional view showing another configuration of a semiconductor device 100.

FIG. 22 illustrates one example of a doping concentration distribution on a line h-h in FIG. 21.

FIG. 23 illustrates another example of a doping concentration distribution on the line h-h.

FIG. 24 illustrates another example of a doping concentration distribution on the line h-h.

FIG. 25 is a cross-sectional view showing another configuration of a semiconductor device 100.

FIG. 26 illustrates another structure example of a high concentration region 86.

FIG. 27 is a cross-sectional view showing another configuration of a semiconductor device 100.

FIG. 28 is a cross-sectional view showing another configuration of a semiconductor device 100.

FIG. 29 is a cross-sectional view showing another example of a semiconductor device 100.

FIG. 30 illustrates an arrangement example of a high concentration region 86 and an emitter region 12 in a top view.

FIG. 31 illustrates some processes in the method for manufacturing the semiconductor device 100 described with reference to FIG. 21 to FIG. 30.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a gravitational direction or to a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to an acceptor concentration set as a negative ion concentration, taking into account of polarities of electric charges. As one example, when the donor concentration is N_{D} and the acceptor concentration is N_{A}, the net doping concentration at any position is given as N_{D}-N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to impurities themselves. For example, a VOH defect in which a vacancy (V), oxygen (O), and hydrogen (H) present in the semiconductor are attached together functions as the donor which supplies electrons. In the present specification, the VOH defect may be referred to as a hydrogen donor.

In the present specification, a description of a P+ type or an N+ type means a higher doping concentration than that of the P type or the N type, and a description of a P− type or an N− type means a lower doping concentration than that of the P type or the N type. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration (atomic density) can be measured by, for example, a secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration in the region may be defined as the donor concentration. Similarly, in a region of the P type, the carrier concentration in the region may be defined as the acceptor concentration. In the present specification, the doping concentration in the N type region may be referred to as the donor concentration, and the doping concentration in the P type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or/cm³ is used to express a concentration per unit volume.

This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As one example, in a silicon semiconductor, a donor concentration of phosphorous or arsenic serving as a donor, or an acceptor concentration of boron (boron) serving as an acceptor is about 99% of chemical concentrations of these. On the other hand, in the silicon semiconductor, a donor concentration of hydrogen serving as a donor is about 0.1% to 10% of a chemical concentration of hydrogen. Each concentration in the present specification may have a value at a room temperature. As the value at a room temperature, a value at 300K (Kelvin) (about 26.9 degrees C.) as one example may be used.

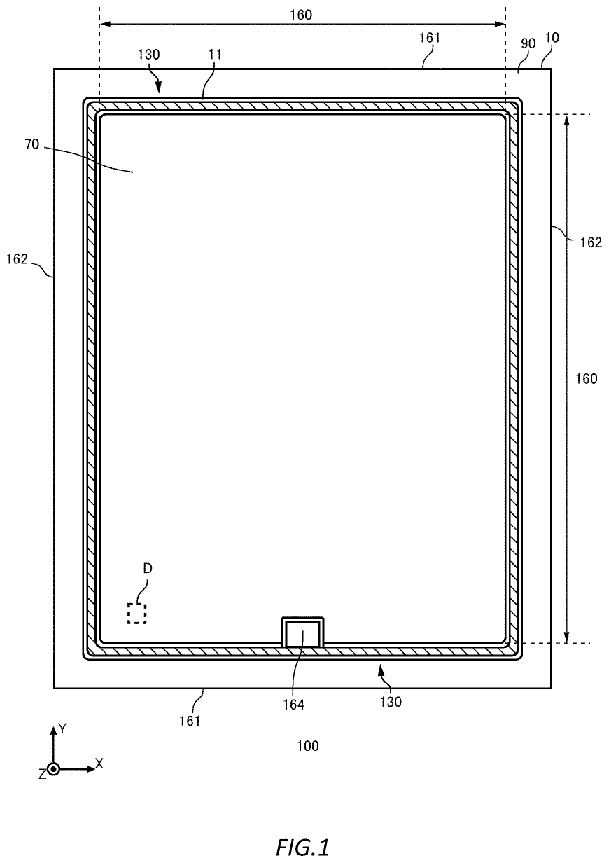

FIG. 1 is a top view showing one example of a semiconductor device 100. FIG. 1 shows a position of each member projected onto an upper surface of a semiconductor substrate 10. In FIG. 1, only some members of the semiconductor device 100 are shown, and illustration of some members is omitted.

The semiconductor device 100 includes the semiconductor substrate 10. The semiconductor substrate 10 is a substrate which is formed of a semiconductor material. Although the semiconductor substrate 10 is a silicon substrate as one example, a material of the semiconductor substrate 10 is not limited to silicon.

The semiconductor substrate 10 has a first end side 161 and a second end side 162 in a top view. Mere reference to a top view in the present specification means the semiconductor substrate 10 being viewed from an upper surface side. The semiconductor substrate 10 in the present example has one set of first end sides 161 facing each other in a top view. In addition, the semiconductor substrate 10 in the present example has one set of second end sides 162 facing each other in a top view. In FIG. 1, the first end sides 161 are parallel to the X axis direction. The second end sides 162 are parallel to the Y axis direction. In addition, the Z axis is perpendicular to the upper surface of the semiconductor substrate 10. In addition, the first end sides 161 are perpendicular to an extending direction or a longitudinal direction of a gate trench portion which will be described below. The second end sides 162 are parallel to the extending direction or the longitudinal direction of the gate trench portion which will be described below.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but illustration thereof is omitted in FIG. 1.

In the present example, the active portion 160 is provided with a transistor portion 70 including a transistor device such as an IGBT. In another example, transistor portions 70 and diode portions including diode devices such as Free Wheel Diodes (FWD) may be alternately arranged along a predetermined array direction at the upper surface of the semiconductor substrate 10. Although one transistor portion 70 is provided in the present example, a plurality of transistor portions 70 may also be provided. A well region of a P+ type or a gate runner may be provided between the transistor portions 70.

The transistor portion 70 has a collector region of the P+ type in a region in contact with the lower surface of the semiconductor substrate 10. In addition, the transistor portion 70 has surface MOS structures, which include emitter regions of an N+ type, base regions of a P− type, drift regions of an N− type, gate conductive portions, and gate dielectric films, periodically arranged on the upper surface side of the semiconductor substrate 10.

The semiconductor device 100 may have one or more pads above the semiconductor substrate 10. The semiconductor device 100 in the present example has a gate pad 164. The semiconductor device 100 may have a pad such as an anode pad, a cathode pad, and a current detection pad. Each pad is arranged in the vicinity of a first end side 161. The vicinity of the first end side 161 refers to a region between the first end side 161 in a top view and the emitter electrode. When the semiconductor device 100 is mounted, each pad may be connected to an external circuit via a wiring line such as a wire.

A gate potential is applied to the gate pad 164. The gate pad 164 is electrically connected to a conductive portion of the gate trench portion of the active portion 160. The semiconductor device 100 includes a gate runner 130 which connects the gate pad 164 and the gate trench portion. In FIG. 1, the gate runner 130 is hatched with diagonal lines.

The gate runner 130 is arranged between the active portion 160 and the first end side 161 or the second end side 162 in a top view. The gate runner 130 in the present example encloses the active portion 160 in a top view. A region enclosed by the gate runner 130 in a top view may be the active portion 160. In addition, the gate runner 130 is connected to the gate pad 164. The gate runner 130 is arranged above the semiconductor substrate 10. The gate runner 130 may be a metal wiring line containing aluminum or the like. The gate runner 130 may be provided separately from the emitter electrode.

A P type outer circumferential well region 11 is provided to overlap the gate runner 130. That is, similarly to the gate runner 130, the P type outer circumferential well region 11 encloses the active portion 160 in a top view. The P type outer circumferential well region 11 is provided to extend with a predetermined width also in a range which does not overlap the gate runner 130. The P type outer circumferential well region 11 is a region of a second conductivity type. The P type outer circumferential well region 11 in the present example is of the P+ type. A doping concentration of the P type outer circumferential well region 11 may be 5.0×10¹⁷ atoms/cm³ or more and 5.0×10¹⁹ atoms/cm³ or less. The doping concentration of the P type outer circumferential well region 11 may be 2.0×10¹⁸ atoms/cm³ or more and 2.0×10¹⁹ atoms/cm³ or less.

The semiconductor device 100 may include a temperature sensing portion (not shown) which is a PN junction diode formed of polysilicon or the like, and a current detection portion (not shown) which simulates an operation of the transistor portion 70 provided in the active portion 160. The temperature sensing portion may be connected to the anode pad and the cathode pad via wiring line. When provided, the temperature sensing portion is preferably provided at a center of the semiconductor substrate 10 in the X axis direction and the Y axis direction.

The semiconductor device 100 in the present example includes an edge termination structure portion 90 between the active portion 160 and the first end side 161 or the second end side 162 in a top view. The edge termination structure portion 90 in the present example is arranged between the outer circumferential gate runner 130 and the first end side 161 or the second end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

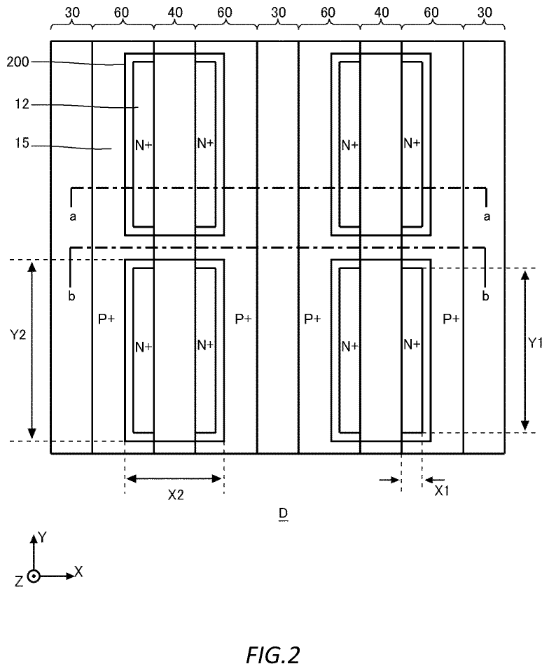

FIG. 2 is one example of an enlarged view of a region D in FIG. 1. The region D is a region which includes the transistor portion 70 of the active portion 160 shown in FIG. 1. FIG. 2 shows a structure of the upper surface of the semiconductor substrate 10 in the region D. In the region D, the semiconductor device 100 includes one or more gate trench portions 40, one or more emitter regions 12, one or more contact regions 15, and one or more polysilicon resistance portions 200. A polysilicon resistance portion 200 is one example of a resistance portion. The resistance portion is a region provided between a lower end of the emitter region 12 and an emitter electrode which will be described below. The resistance portion in the present example has a structure obtained by forming a resistance material into a film or a layer. Instead of the polysilicon resistance portion 200, for example, conductive diamond-like carbon may be used as the resistance portion.

The semiconductor device 100 may further include one or more dummy trench portions 30. In the present specification, a gate trench portion 40 and a dummy trench portion 30 may be each referred to as a trench portion. When a term “trench portion” is simply mentioned in the present specification, the trench portion may be either the gate trench portion 40 or the dummy trench portion 30.

The gate trench portion 40 has a longitudinal side in a first direction at the upper surface of the semiconductor substrate 10. In the present example, the gate trench portion 40 is provided to extend in the Y axis direction which is the first direction. The gate trench portion 40 is provided from the upper surface of the semiconductor substrate 10 to the inside of the semiconductor substrate 10. A gate conductive portion formed of a conductive material such as polysilicon is arranged inside the gate trench portion 40. The gate conductive portion is electrically connected to the gate runner 130 (see FIG. 1), and a predetermined gate voltage is applied thereto.

A plurality of trench portions are arrayed at predetermined intervals in a second direction intersecting with the first direction. The second direction in the present example is the X axis direction orthogonal to the first direction (the Y axis direction). As shown in FIG. 2, a trench portion adjacent to a gate trench portion 40 in the Y axis direction may be a dummy trench portion 30. Note that, however, gate trench portions 40 may be arranged to be adjacent to each other in the Y axis direction. As shown in FIG. 2, a trench portion adjacent to a dummy trench portion 30 in the Y axis direction may be a gate trench portion 40, or may be a dummy trench portion 30. In the Y axis direction, one or more dummy trench portions 30 may be arranged between two gate trench portions 40.

A region that is sandwiched between two trench portions in the X axis direction and that is of the semiconductor substrate 10 is defined as a mesa portion 60. Each end of the mesa portion 60 in the X axis direction is a boundary portion with each trench portion. A depth position of a lower end of the mesa portion 60 is to be the same as a depth position of a lower end of at least one of the trench portions on both sides.

An emitter region 12 is a region of the N+ type which is provided to be exposed on the upper surface in the semiconductor substrate 10. The emitter region 12 is in contact with the gate trench portion 40. The emitter region 12 may be provided in each mesa portion 60 that is in contact with the gate trench portion 40. A length of one emitter region 12 in the Y axis direction is defined as Y1, and a length thereof in the X axis direction is defined as X1. The length Y1 is longer than the length X1. Each emitter region 12 may have a band shape extending in the Y axis direction. The length Y1 may be more than or equal to twice, may be more than or equal to three times, or may be more than or equal to five times, the length X1. Setting the length Y1 greater than the length X1 can increase a length in the Y axis direction of a channel formed below the emitter region 12, and can improve a channel density. The emitter region 12 may be in contact with only one trench portion (in FIG. 2, the gate trench portion 40) of the trench portions on both sides of the mesa portion 60, and may not be in contact with another trench portion (in FIG. 2, the dummy trench portion 30).

As shown in FIG. 2, in one mesa portion 60, a plurality of emitter regions 12 may be arranged to be spaced apart from each other in the Y axis direction. A distance between two emitter regions 12 which are adjacent to each other in the Y axis direction may be smaller than the length Y1, or may be less than or equal to half, may be less than or equal to one fourth, or may be less than or equal to one tenth, the length Y1. In another example, only one emitter region 12 may be continuously arranged in the Y axis direction of one mesa portion 60. In this case, the length Y1 of the emitter region 12 may be more than or equal to half, or may be more than or equal to three fourth, a length of the mesa portion 60 in the Y axis direction.

A contact region 15 is a region of the P type which is exposed on the upper surface of the semiconductor substrate 10 in the mesa portion 60 and is connected to an emitter electrode. The contact region 15 may be a partial region of a base region which will be described below, or may be a region of the P+ type having a higher doping concentration than the base region. When the contact region 15 has a higher doping concentration than the base region, a contact resistance between the contact region 15 and the emitter electrode can be reduced.

The polysilicon resistance portion 200 is provided between the emitter region 12 and the emitter electrode which will be described below. The polysilicon resistance portion 200 in the present example is formed of polysilicon to which an impurity is added. At room temperature (25 degrees C.), resistivity (Ω·m) of the polysilicon resistance portion 200 is greater than resistivity of the emitter electrode, and is smaller than resistivity of a dielectric film such as a gate dielectric film or an interlayer dielectric film which will be described below. A resistance value of the polysilicon resistance portion 200 in the depth direction may be higher than a resistance value of the emitter region 12 in the depth direction.

The polysilicon resistance portion 200 in the present example covers an entirety of the emitter region 12 in a top view. That is, the emitter region 12 is not in contact with the emitter electrode. The polysilicon resistance portion 200 is arranged so as not to cover at least part of the contact region 15. As a result, the contact region 15 can be in contact with an emitter electrode 52. As shown in FIG. 2, the contact region 15 may be in contact with the dummy trench portion 30 at the upper surface 21. The polysilicon resistance portion 200 may be arranged so as not to cover a boundary portion between the contact region 15 and the dummy trench portion 30. The polysilicon resistance portion 200 may be arranged so as not to overlap the dummy trench portion 30.

The polysilicon resistance portion 200 may cover or may not cover part of the contact region 15. The polysilicon resistance portion 200 in the present example covers a boundary portion with the emitter region 12 of the contact region 15. An area of a part that is of the contact region 15 at the upper surface 21 and that is covered with the polysilicon resistance portion 200 may be smaller than an area of a part that is not covered with the polysilicon resistance portion 200. This can ensure a contact area between the contact region 15 and the emitter electrode 52 and reduce the contact resistance. The area of the part that is of the contact region 15 at the upper surface 21 and that is covered with the polysilicon resistance portion 200 may be less than or equal to half, may be less than or equal to one fourth, or may be less than or equal to one tenth, the area of the part that is not covered with the polysilicon resistance portion 200.

A length of one polysilicon resistance portion 200 in the Y axis direction is defined as Y2, and a length thereof in the X axis direction is defined as X2. The length Y2 may be the same as or greater than the length Y1. The length X2 may be the same as the length X1, or may be greater than the length X1. In the example shown in FIG. 2, the length X2 is greater than a length twice the length X1, and is greater than the length twice the length X1 plus a width of the trench portion. The length Y2 in the present example is longer than the length X2. Each polysilicon resistance portion 200 may have a band shape extending in the Y axis direction. The length Y2 may be more than or equal to twice, may be more than or equal to three times, or may be more than or equal to five times, the length X2.

The polysilicon resistance portion 200 may overlap only one trench portion (in FIG. 2, the gate trench portion 40) of the trench portions on both sides of the mesa portion 60, and may not overlap another trench portion (in FIG. 2, the dummy trench portion 30).

As shown in FIG. 2, in one mesa portion 60, a plurality of polysilicon resistance portions 200 may be discretely arranged in the Y axis direction. The polysilicon resistance portions 200 may be provided for each of the emitter regions 12 which are discretely arranged in the Y axis direction. In another example, one polysilicon resistance portion 200 may cover two or more emitter regions 12 which are discretely arranged in the Y axis direction. In addition, only one polysilicon resistance portion 200 may be continuously arranged in the Y axis direction of one mesa portion 60. In this case, one polysilicon resistance portion 200 may cover all emitter regions 12 which are discretely arranged in the Y axis direction.

Emitter regions 12 may be arranged on both sides of one gate trench portion 40 in the Y axis direction. In this case, one polysilicon resistance portion 200 may cover the emitter regions 12 on both sides of one gate trench portion 40. The polysilicon resistance portion 200 in this case is arranged also above the gate trench portion 40.

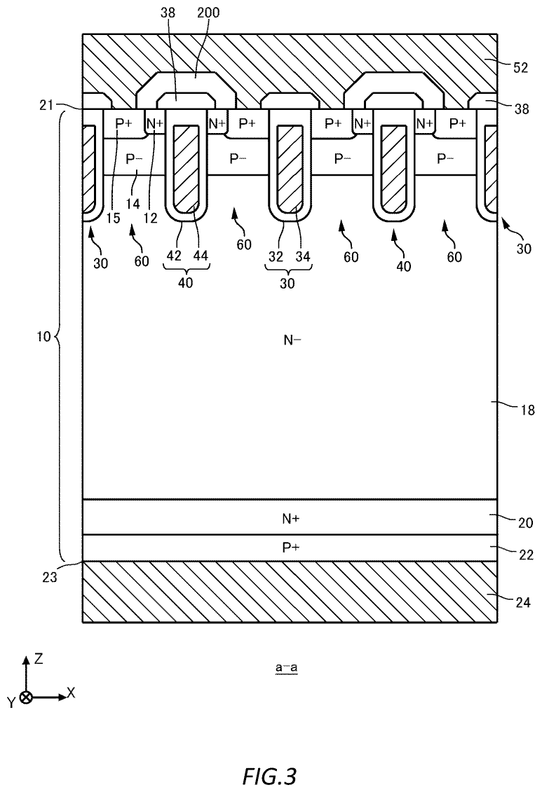

FIG. 3 illustrates one example of a cross section taken along a line a-a in FIG. 2. A cross section a-a is an XZ cross section passing through an emitter region 12 and a polysilicon resistance portion 200. A semiconductor device 100 in the present example includes a semiconductor substrate 10, an interlayer dielectric film 38, an emitter electrode 52, a collector electrode 24, and the polysilicon resistance portion 200, in the cross section.

The emitter electrode 52 is provided above an upper surface 21 of the semiconductor substrate 10. Part of the upper surface 21 of the semiconductor substrate 10 is covered with the interlayer dielectric film 38 or the polysilicon resistance portion 200. The emitter electrode 52 is in contact with at least part of the upper surface 21 of the semiconductor substrate 10 which is not covered with the interlayer dielectric film 38 or the polysilicon resistance portion 200. The emitter electrode 52 in the present example is in contact with a contact region 15, and is not in contact with the emitter region 12.

The emitter electrode 52 is formed of a material containing metal. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, titanium nitride, or the like below a region formed of aluminum or the like. The barrier metal may be in contact with the semiconductor substrate 10. The emitter electrode 52 may have a metal plug formed tungsten or the like below the region formed of aluminum or the like. The metal plug may have a portion which is formed below the upper surface 21 of the semiconductor substrate 10.

The collector electrode 24 is provided on a lower surface 23 of the semiconductor substrate 10. The collector electrode 24 is formed of a metal material such as aluminum similarly to the emitter electrode 52. In the present specification, a direction in which the emitter electrode 52 is connected to the collector electrode 24 (the Z axis direction) is referred to as a depth direction.

The interlayer dielectric film 38 is provided on an upper surface 21 of the semiconductor substrate 10. The interlayer dielectric film 38 is a film which includes at least one of a dielectric film such as silicate glass to which an impurity such as boron or phosphorous is added, a thermal oxide film, or another dielectric film. The interlayer dielectric film 38 may cover each trench portion. In addition, the interlayer dielectric film 38 may not be provided. In this case, the polysilicon resistance portion 200 may be in contact with a dielectric film at an upper end of the trench portion.

A base region 14 of the P− type is provided in each mesa portion 60. The base region 14 is in contact with a gate trench portion 40. The base region 14 may be in contact with each of trench portions on both sides of the mesa portion 60. At least part of the base region 14 is provided below the emitter region 12. The base region 14 may be in contact with the emitter region 12. When a predetermined ON voltage is applied to the gate trench portion 40, a surface layer of the base region 14 in contact with the gate trench portion 40 is inverted to a region of the N type to form a channel. The emitter region 12 is electrically connected by the channel to a drift region 18 which will be described below.

The base region 14 is provided also below the contact region 15. The base region 14 is in contact with the contact region 15. As described above, part of the base region 14 may function as the contact region 15. The base region 14 in the present example is a region of the P− type having a lower doping concentration than the contact region 15. A doping concentration of the base region 14 may be 5.0×10¹⁶ atoms/cm³ or more and 1.0×10¹⁸ atoms/cm³ or less.

The semiconductor substrate 10 has the drift region 18 of the N− type. The emitter region 12 has a higher doping concentration than the drift region 18. The drift region 18 is provided below the base region 14. The drift region 18 may be in contact with the base region 14.

In another example, an accumulation region of the N+ type having a higher doping concentration than the drift region 18 may be provided between the drift region 18 and the base region 14. Providing the accumulation region can produce an electron injection enhancement effect to decrease an ON voltage of the semiconductor device 100.

A collector region 22 of the P+ type is provided between the drift region 18 and the lower surface 23 of the semiconductor substrate 10. A doping concentration of the collector region 22 is higher than the doping concentration of the base region 14. The collector region 22 may include the same acceptor as or an acceptor different from that of the base region 14. The acceptor of the collector region 22 is, for example, boron. An element serving as the acceptor is not limited to the example described above. The collector region 22 is exposed on the lower surface 23 of the semiconductor substrate 10, and is connected to the collector electrode 24. The collector electrode 24 may be in contact with an entirety of the lower surface 23 of the semiconductor substrate 10.

A buffer region 20 of the N+ type may be provided between the drift region 18 and the collector region 22. A doping concentration of the buffer region 20 is higher than a doping concentration of the drift region 18. The buffer region 20 may have one or more concentration peaks with a doping concentration higher than that of the drift region 18. A doping concentration at a concentration peak refers to a doping concentration at a local maximum of the concentration peak. In addition, an average doping concentration in a region where a doping concentration distribution is substantially flat may be used as the doping concentration of the drift region 18.

The buffer region 20 may be formed through ion implantation of an N type dopant such as hydrogen (proton) or phosphorous. The buffer region 20 in the present example is formed through ion implantation of hydrogen. The buffer region 20 may function as a field stopper layer which prevents a depletion layer expanding from a lower end of the base region 14 from reaching the collector region 22.

One or more gate trench portions 40 are provided on an upper surface 21 side of the semiconductor substrate 10. In the present example, a plurality of gate trench portions 40 are provided on the upper surface 21 side of the semiconductor substrate 10. In the present example, each gate trench portion 40 penetrates the base region 14 from the upper surface 21 of the semiconductor substrate 10, to reach the drift region 18. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

The gate trench portion 40 has a groove-shaped gate trench, a gate dielectric film 42, and a gate conductive portion 44 which are provided at the upper surface 21 of the semiconductor substrate 10. The gate conductive portion 44 is formed of polysilicon which is a conductive material. The gate dielectric film 42 is provided to cover an inner wall of the gate trench. The gate dielectric film 42 may be formed by oxidizing or nitriding a semiconductor on the inner wall of the gate trench. The gate conductive portion 44 is provided farther inward than the gate dielectric film 42 inside the gate trench. That is, the gate dielectric film 42 insulates the gate conductive portion 44 from the semiconductor substrate 10.

The gate conductive portion 44 in the gate trench portion 40 may be provided to be longer than the base region 14 in the depth direction. The gate trench portion 40 in the cross section is covered with the interlayer dielectric film 38 on the upper surface 21 of the semiconductor substrate 10. The gate conductive portion 44 is electrically connected to a gate runner 130 at a position other than the cross section shown in FIG. 3.

A dummy trench portion 30 has a structure similar to that of the gate trench portion 40. The dummy trench portion 30 in the present example has a groove-shaped dummy trench, a dummy dielectric film 32, and a dummy conductive portion 34. Structures of the dummy trench, the dummy dielectric film 32, and the dummy conductive portion 34 are similar to those of the gate trench, the gate dielectric film 42, and the gate conductive portion 44. The dummy trench portion 30 in the cross section is covered with the interlayer dielectric film 38 on the upper surface 21 of the semiconductor substrate 10. The dummy conductive portion 34 is electrically connected to the emitter electrode 52 at a position other than the cross section shown in FIG. 3.

The polysilicon resistance portion 200 is provided between the emitter region 12 and the emitter electrode 52. The polysilicon resistance portion 200 in the present example covers the gate trench portion 40 and two emitter regions 12 provided on both sides of the gate trench portion 40 in the Y axis direction. The polysilicon resistance portion 200 may be arranged so as to overlap an entirety of the gate trench portion 40 and an entirety of two emitter regions 12 in the X axis direction. The polysilicon resistance portion 200 may also cover part of the contact region 15, beyond the boundary portion between the emitter region 12 and the contact region 15 at the upper surface 21 of the semiconductor substrate 10.

The semiconductor device 100 in the present example achieves both a relatively low saturation current and a relatively low ON voltage by providing the polysilicon resistance portion 200 and forming the emitter region 12 which has a longitudinal side in the Y axis direction. A MOS structure provided at the upper surface 21 of the semiconductor substrate 10 has a saturation characteristic that saturates a collector current even if a collector/emitter voltage is increased. As a result, the semiconductor device 100 has a short-circuit withstand capability characteristic that prevents the device from being destructed if within a certain period of time in a short-circuit state where a great current and a great voltage are applied at the same time. Since a saturation current becomes extremely great when the MOS structure is formed in all mesa portions 60 in a state where device miniaturization is advanced, the saturation current may be suppressed with a thinning-out structure in which the MOS structure is not formed in some mesa portions 60, a ladder structure in which emitter regions 12 having longitudinal sides in the X axis direction are discretely arranged in the Y axis direction, or the like. However, suppressing the saturation current with such a structure increases the ON voltage.

A current saturation characteristic of the MOS structure is expressed by Expression 1 as follows.

$$Isat = \frac{Z μ nCox}{Lch} [ \frac{1}{2} {( V ge - V th )}^{2} ] \qquad ( Expression 1 )$$

Isat represents the saturation current, Z represents a total emitter width of the emitter region 12 (that is, a total length in the Y axis direction), un represents mobility of electrons, Cox represents a capacitance of the gate dielectric film 42, Lch represents a channel length in the Z axis direction, Vge represents a gate-emitter voltage, and Vth represents a threshold voltage.

A channel resistance Rch of the MOS structure is expressed by Expression 2 as follows.

$$Rch = \frac{Lch}{Z μ nCox ( V ge - V th )} \qquad ( Expression 2 )$$

Comparing Expression 1 and Expression 2, it can be seen that decreasing the saturation current Isat increases the channel resistance Rch, and also increasing the saturation current Isat decreases the channel resistance Rch. That is, there is a trade-off correlation in which decreasing the saturation current in order to improve short-circuit withstand capability of the semiconductor device 100 increases the ON voltage. For example, in a thinning-out emitter structure, the emitter region 12 is formed in some mesa portions 60, and thus supply of electron current to the drift region 18 becomes sparse in the X axis direction, a current flow becomes non-uniform, and the ON voltage increases. In addition, in the ladder structure in which the emitter regions 12 having longitudinal sides in the X axis direction are discretely arranged in the Y axis direction, it is difficult to increase the length Z (which corresponds to a channel width) of a contact between the gate trench portion 40 and the emitter region 12.

In contrast, in the semiconductor device 100, the saturation current is suppressed by providing the polysilicon resistance portion 200 between the emitter electrode 52 and the emitter region 12. When the semiconductor device 100 is turned on, a current flows between the emitter electrode 52 and the emitter region 12 via the polysilicon resistance portion 200. Therefore, a potential of the emitter region 12 varies depending on magnitude of the current flowing through the polysilicon resistance portion 200. Since the current flows from the emitter region 12 to the emitter electrode 52, when the current flowing through the polysilicon resistance portion 200 is greater, the potential of the emitter region 12 becomes higher. When the current flowing through the polysilicon resistance portion 200 is small, the potential of the emitter region 12 increases only slightly.

Since the ON voltage applied to the gate conductive portion 44 is substantially constant voltage, increasing the current flowing through the polysilicon resistance portion 200 decreases a potential difference between the gate conductive portion 44 and the emitter region 12, and decreases a voltage applied to the gate dielectric film 42. On the other hand, when the current flowing through the polysilicon resistance portion 200 is small, the voltage applied to the gate dielectric film 42 becomes relatively great. Therefore, the saturation current flowing through the MOS structure can be suppressed.

In the semiconductor device 100, the total emitter width Z is increased and the ON voltage is decreased by providing the emitter region 12 having a longitudinal side in the Y axis direction. This can achieve both a low saturation current and a low ON voltage.

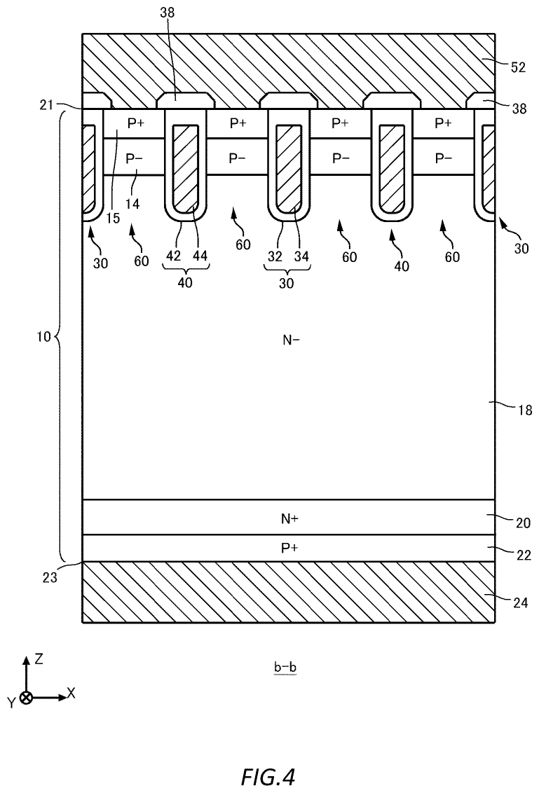

FIG. 4 illustrates one example of a cross section taken along a line b-b in FIG. 2. A cross section b-b is an XZ cross section which does not pass through an emitter region 12 and a polysilicon resistance portion 200 and passes through a contact region 15.

In the cross section b-b, the emitter region 12 is not provided in each mesa portion 60. In each mesa portion 60, the contact region 15 is provided at an upper surface 21 of a semiconductor substrate 10. The contact region 15 is in contact with an emitter electrode 52.

In the cross section b-b, the polysilicon resistance portion 200 is not provided. The contact region 15 and an interlayer dielectric film 38 are in contact with the emitter electrode 52. A structure of the cross section b-b is similar to a structure of the cross section a-a, except that the emitter region 12 and the polysilicon resistance portion 200 are not provided.

In the examples shown in FIG. 2 to FIG. 4, in each mesa portion 60, the emitter region 12 is provided at the same position in the Y axis. Similarly, in each mesa portion 60, the polysilicon resistance portion 200 is also provided at the same position in the Y axis direction. In another example, a position of the emitter region 12 in any one mesa portions 60 in the Y axis direction may be different from a position of the emitter region 12 in another mesa portion 60 in the Y axis direction. Similarly, a position of the polysilicon resistance portion 200 in any one mesa portions 60 in the Y axis direction may be different from a position of the polysilicon resistance portion 200 in another mesa portion 60 in the Y axis direction.

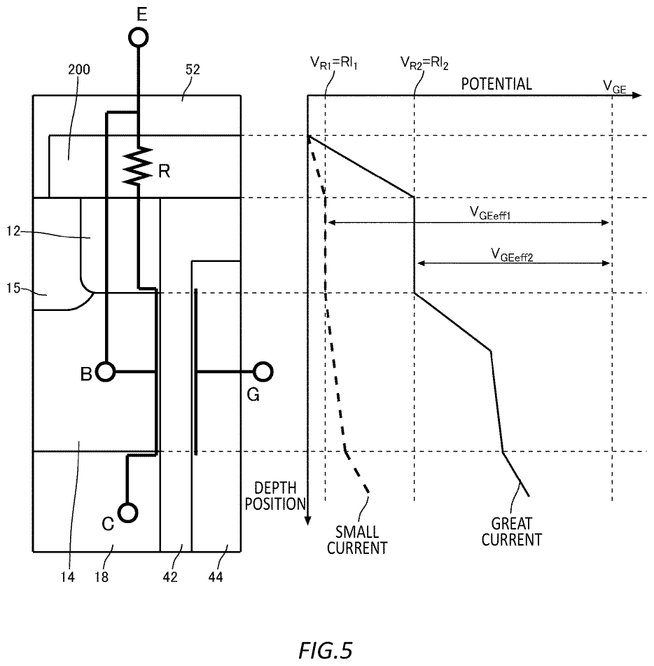

FIG. 5 illustrates one example of potential distributions of a polysilicon resistance portion 200, an emitter region 12, a base region 14, and a drift region 18 in a depth direction. FIG. 5 shows a schematic view of a semiconductor device 100 including the polysilicon resistance portion 200, the emitter region 12, the base region 14, and the drift region 18 alongside a diagram showing the potential distributions. An axis representing a depth position in the potential distribution diagram corresponds to a depth position in the schematic view. In the schematic view, illustration of an interlayer dielectric film 38 is omitted. In the schematic view, an emitter electrode 52, the base region 14, a collector region 22, and a gate conductive portion 44 are schematically shown as terminals E, B, C, and G. The schematic view shows wiring lines which connect respective terminals. A resistance R in the schematic view represents a resistance component of the polysilicon resistance portion 200. The schematic view also shows a capacitance component by a gate dielectric film 42 between the base region 14 and the gate conductive portion 44. The potential distribution diagram indicates, by a dashed line, a potential distribution for a case where a small current I₁ smaller than a rated current flows between an emitter and a collector, and indicates, by a solid line, a potential distribution for a case where a great current I₂ as great as a saturation current flows.

When the polysilicon resistance portion 200 is provided, a potential of the emitter region 12 varies depending on a current flowing through the polysilicon resistance portion 200 and the resistance R of the polysilicon resistance portion 200. When the great current 12 flows, the potential of the emitter region 12 significantly increases. On the other hand, when the small current 11 flows, the potential of the emitter region 12 increases only slightly. Since a gate voltage V_{GE} Which drives a MOS structure is constant, a potential difference V_{GEeff2} applied to the gate dielectric film 42 becomes small in a great current region. On the other hand, a potential difference V_{GEeff1} applied to the gate dielectric film 42 becomes relatively great in a small current region. Accordingly, the saturation current can be significantly suppressed. The semiconductor device 100 can be driven with a great gate voltage/emitter voltage difference in the small current region, and can be driven with a small gate voltage/emitter voltage difference in the great current region.

In the semiconductor device 100 in the present example, providing the polysilicon resistance portion 200 can reduce the saturation current. On the other hand, in the semiconductor device 100, increasing a total emitter width Z can increase the saturation current. That is, the semiconductor device 100 can reduce an ON voltage while maintaining or decreasing the saturation current by increasing the total emitter width Z and increasing the saturation current within a range where the saturation current is reduced by the polysilicon resistance portion 200.

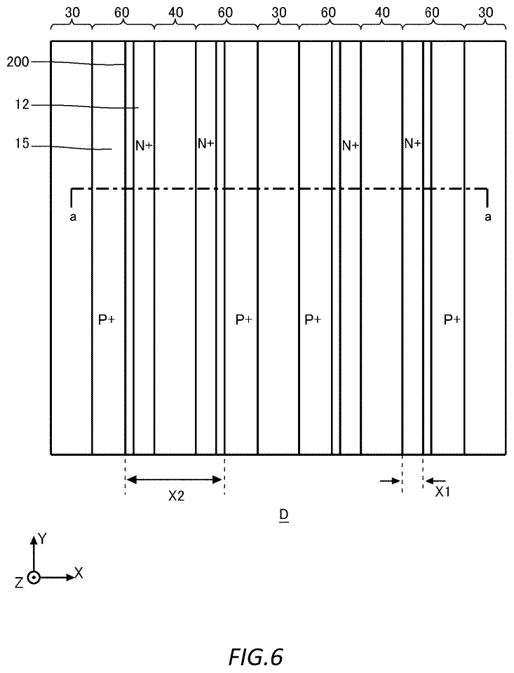

FIG. 6 is another example of the enlarged view of the region D in FIG. 1. In a semiconductor device 100 in the present example, only one emitter region 12 is continuously provided in the Y axis direction in one mesa portion 60. Only one polysilicon resistance portion 200 is provided to cover the emitter region 12 in one mesa portion 60. Other structures are similar to those of the semiconductor device 100 according to any of the aspects described with reference to FIG. 1 to FIG. 5. For example, a cross section a-a in FIG. 6 has a structure similar to the cross section a-a shown in FIG. 3.

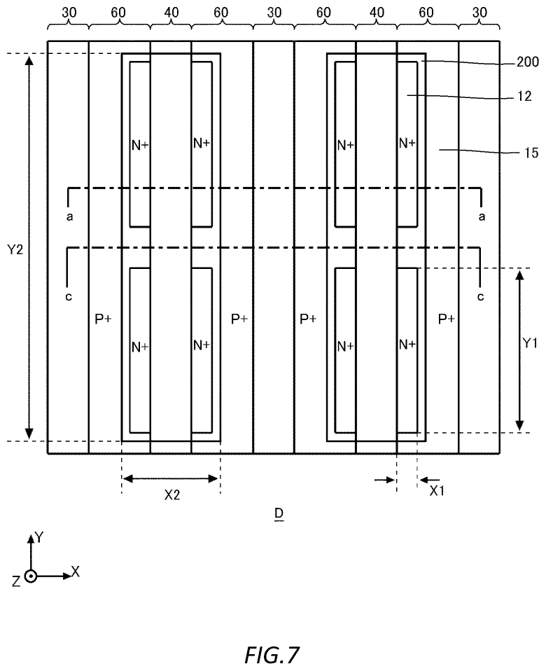

FIG. 7 is another example of the enlarged view of the region D in FIG. 1. In a semiconductor device 100 in the present example, a plurality of emitter regions 12 are discretely provided in the Y axis direction in one mesa portion 60. In a mesa portion 60 in the present example, one polysilicon resistance portion 200 is continuously arranged over two or more emitter regions 12 in the Y axis direction. One polysilicon resistance portion 200 may cover an entirety of two or more emitter regions 12. A plurality of polysilicon resistance portions 200 may be arranged in the Y axis direction in the mesa portion 60. Each polysilicon resistance portion 200 may be arranged over two or more emitter regions 12. The numbers of emitter regions 12 covered with respective polysilicon resistance portions 200 may be the same or may be different from each other.

Structures other than the emitter region 12 and the polysilicon resistance portion 200 are similar to those of the semiconductor device 100 according to any of the aspects described with reference to FIG. 1 to FIG. 5. For example, a cross section a-a in FIG. 7 has a structure similar to the cross section a-a shown in FIG. 3. Note that, however, a structure of a cross section c-c in the present example is different from the structure of the cross section b-b shown in FIG. 4.

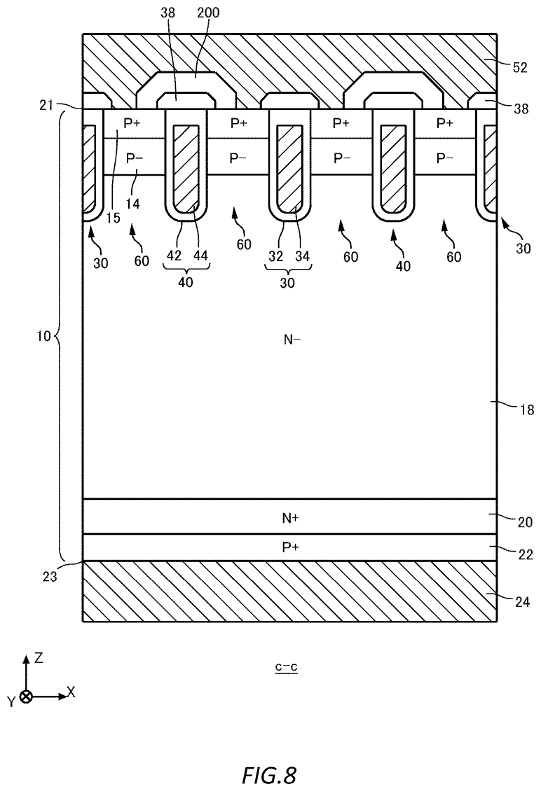

FIG. 8 illustrates one example of a cross section c-c in FIG. 7. The cross section c-c is an XZ cross section which does not pass through an emitter region 12 and passes through a polysilicon resistance portion 200. The emitter region 12 is not provided in a mesa portion 60 in the cross section. A contact region 15 is provided in a region that is in contact with a gate trench portion 40 at an upper surface 21. The polysilicon resistance portion 200 covers an entirety of the gate trench portion 40 in the X axis direction and part of the contact region 15. The polysilicon resistance portion 200 in the present example covers a boundary portion that is of the contact region 15 and that is in contact with the gate trench portion 40, and does not cover a boundary portion that is in contact with a dummy trench portion 30. Structures other than the contact region 15 and the polysilicon resistance portion 200 are similar to those in the cross section b-b shown in FIG. 4.

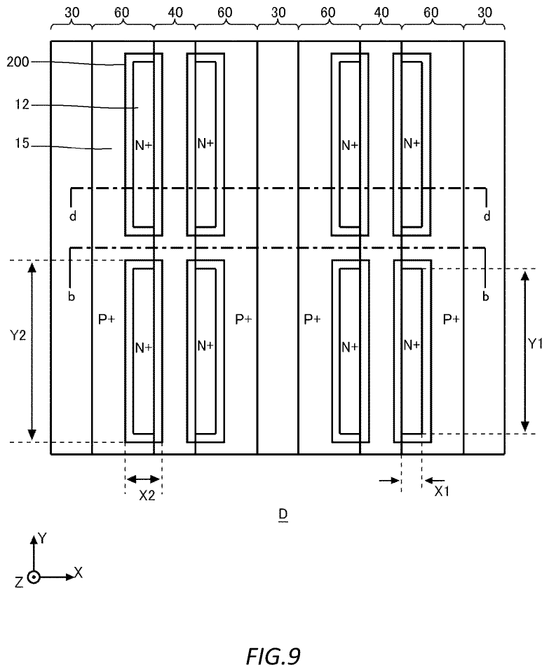

FIG. 9 is another example of the enlarged view of the region D in FIG. 1. Structures of a semiconductor device 100 in the present example other than a polysilicon resistance portion 200 are similar to those of the semiconductor device 100 according to any of the aspects described with reference to FIG. 1 to FIG. 8. The polysilicon resistance portion 200 in the present example covers emitter regions 12 which are arranged on both sides of a gate trench portion 40 in the X axis direction, and does not cover at least part of the gate trench portion 40 between the two emitter regions 12.

Structures other than the polysilicon resistance portion 200 are similar to those of the semiconductor device 100 according to any of the aspects described with reference to FIG. 1 to FIG. 8. For example, a cross section b-b in FIG. 9 has a structure similar to the cross section b-b shown in FIG. 4. Note that, however, a structure of a cross section d-d in the present example is different from the structure of the cross section a-a shown in FIG. 2.

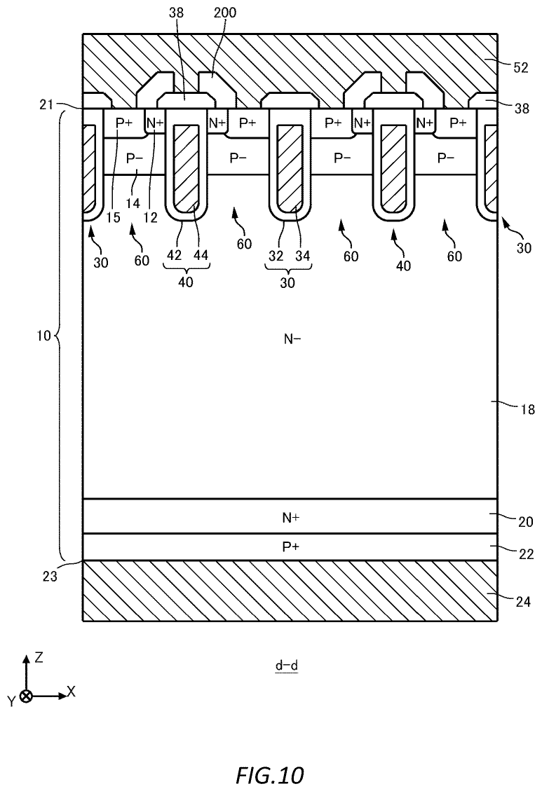

FIG. 10 illustrates one example of a cross section d-d in FIG. 9. The cross section d-d is an XZ cross section passing through an emitter region 12 and a polysilicon resistance portion 200. In the cross section d-d, the polysilicon resistance portion 200 does not cover at least part of a gate trench portion 40. The polysilicon resistance portion 200 may not overlap a central portion of the gate trench portion 40 in the X axis direction which is sandwiched between two emitter regions 12. The polysilicon resistance portion 200 may overlap a boundary portion that is of the gate trench portion 40 and that is in contact with the emitter region 12. Structures other than the polysilicon resistance portion 200 are similar to those in the cross section a-a shown in FIG. 3.

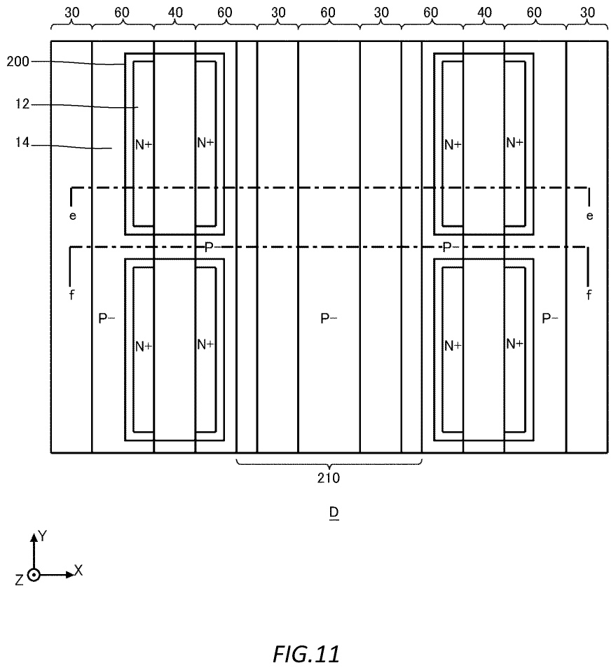

FIG. 11 is another example of the enlarged view of the region D in FIG. 1. A semiconductor device 100 in the present example includes a trench contact portion 210. Structures other than the trench contact portion 210 may be similar to those of the semiconductor device 100 according to any of the aspects described with reference to FIG. 1 to FIG. 10. In the semiconductor device 100 in the present example, a base region 14 in stead of a contact region 15 is exposed on an upper surface 21 of a semiconductor substrate 10, but the contact region 15 may be exposed on the upper surface 21 of the semiconductor substrate 10 similarly to the examples shown in FIG. 1 to FIG. 10.

The trench contact portion 210 is a concave portion which is formed from the upper surface 21 of the semiconductor substrate 10 to the inside of the semiconductor substrate 10. The concave portion is filled with an emitter electrode 52 therein. The emitter electrode 52 is in contact with the semiconductor substrate 10 on a side surface and a bottom surface of the trench contact portion 210. This allows an increase in a contact area between the emitter electrode 52 and the semiconductor substrate 10.

The trench contact portion 210 overlaps a dummy trench portion 30 in a top view. The trench contact portion 210 may be provided in a range that is wider than the dummy trench portion 30 in the X axis direction. The trench contact portion 210 may be provided in a range that is wider than the dummy trench portion 30 in the Y axis direction.

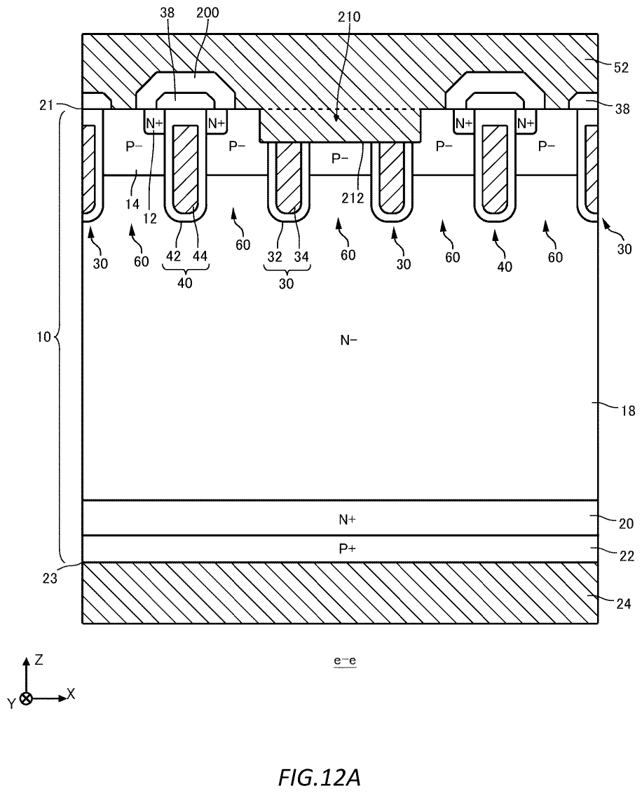

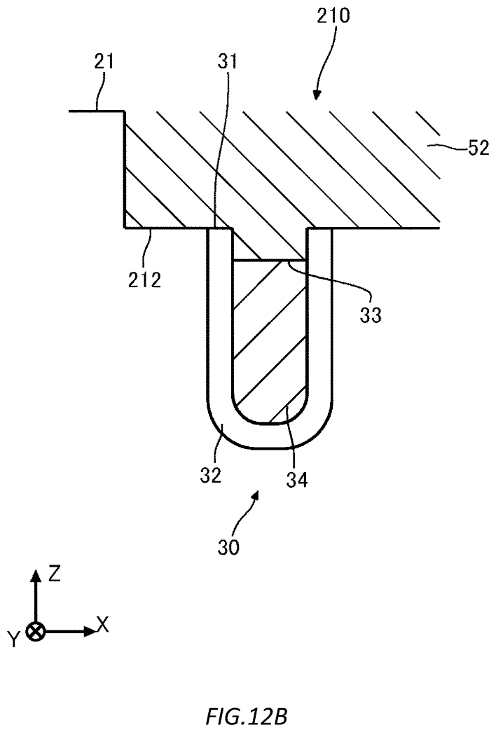

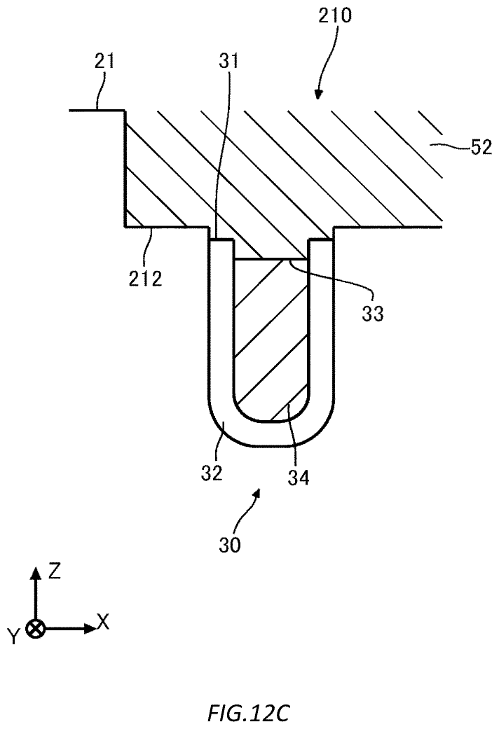

FIG. 12A illustrates one example of a cross section e-e in FIG. 11. The cross section e-e is an XZ cross section passing through an emitter region 12 and a polysilicon resistance portion 200. Structures in the cross section e-e other than the vicinity of a trench contact portion 210 are similar to those in the cross section a-a in FIG. 3 or the cross section d-d in FIG. 10.

As described above, the trench contact portion 210 is provided from an upper surface 21 to the inside of a semiconductor substrate 10, and is filled with an emitter electrode 52 therein. A dummy trench portion 30 is formed at a bottom surface of the trench contact portion 210. A dummy conductive portion 34 of the dummy trench portion 30 is connected to the emitter electrode 52 inside the trench contact portion 210. This allows application of an emitter potential to the dummy conductive portion 34.

One or two or more dummy trench portions 30 may be provided at a bottom surface 212 of one trench contact portion 210. The trench contact portion 210 may be provided in common for two or more dummy trench portions 30 which are arranged to be sandwiched between two gate trench portions 40 in the X axis direction. That is, one trench contact portion 210 is provided between two gate trench portions 40. One or more dummy trench portions 30 between two gate trench portions 40 may be provided at the bottom surface 212 of one trench contact portion 210. Such a structure allows easy provision of the trench contact portion 210 even if an interval between trench portions is decreased.

A depth position of a lower end of the dummy trench portion 30 provided at the bottom surface 212 of the trench contact portion 210 may be the same as or different from a depth position of a lower end of a gate trench portion 40. The lower end of the dummy trench portion 30 may be arranged below the lower end of the gate trench portion 40.

FIG. 12B is an enlarged view of the vicinity of the dummy trench portion 30 shown in FIG. 12A. An upper end 33 of the dummy conductive portion 34 in the present example is arranged below the bottom surface 212 of the trench contact portion 210. The upper end 33 is a portion that is of the dummy conductive portion 34 and that is arranged at the uppermost position. A depth position of the bottom surface 212 in the present example is a depth position of the bottom surface 212 that is closest to a dummy dielectric film 32.

An upper end 31 of the dummy dielectric film 32 may be provided at the same depth position as that of the bottom surface 212. The upper end 31 is a portion that is of the dummy dielectric film 32 and that is arranged at the uppermost position. It should be noted that, as shown in FIG. 12A, the upper end 33 may be arranged at the same depth position as that of the bottom surface 212.

FIG. 12C is another example of the enlarged view of the vicinity of the dummy trench portion 30 shown in FIG. 12A. In the present example, the upper end 31 of the dummy dielectric film 32 is arranged below the bottom surface 212 and above the upper end 33 of the dummy conductive portion 34. A structure shown in FIG. 12C improves coverage of a film such as the bottom surface 212 which covers the semiconductor substrate 10, the dummy dielectric film 32, and the dummy conductive portion 34 (for example, the emitter electrode 52 or a protective film which covers the emitter electrode 52), and improves efficiency percentage. In the example shown in FIG. 12B or FIG. 12C, at least some of the bottom surface 212, the upper end 31, and the upper end 33 are arranged to form a step or steps, but each of boundary portions between the bottom surface 212, the upper end 31, and the upper end 33 may be curved. An etchant used when the trench contact portion 210 is formed may have different removal rates for the semiconductor substrate 10, the dummy dielectric film 32, and the dummy conductive portion 34. Structures in FIG. 12B and FIG. 12C can be formed by selecting the etchant.

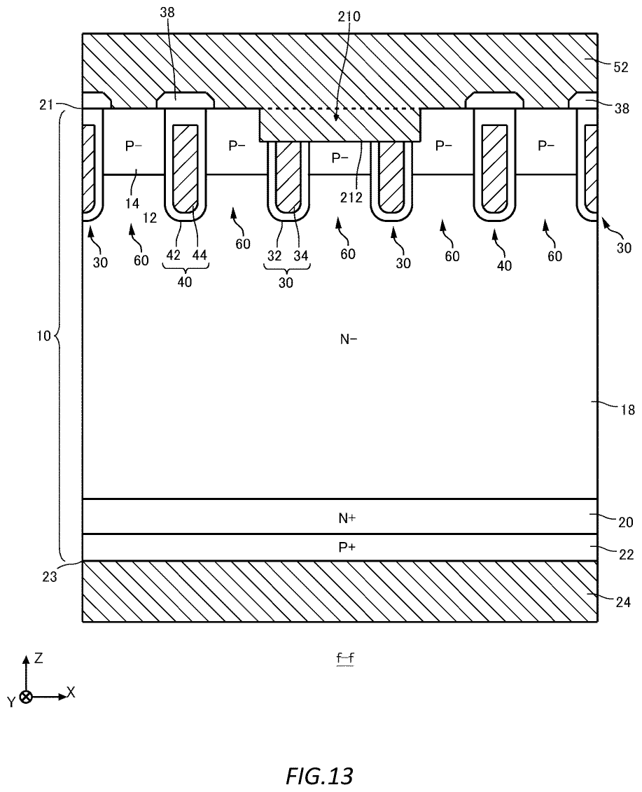

FIG. 13 illustrates one example of a cross section f-f in FIG. 11. The cross section f-f is an XZ cross section which does not pass through an emitter region 12 and a polysilicon resistance portion 200 and passes through a base region 14. Structures of a trench contact portion 210 and a dummy trench portion 30 in the cross section f-f are similar to those in the cross section e-e shown in FIG. 12A. Structures other than the trench contact portion 210 and the dummy trench portion 30 are similar to those in the cross section b-b in FIG. 4.

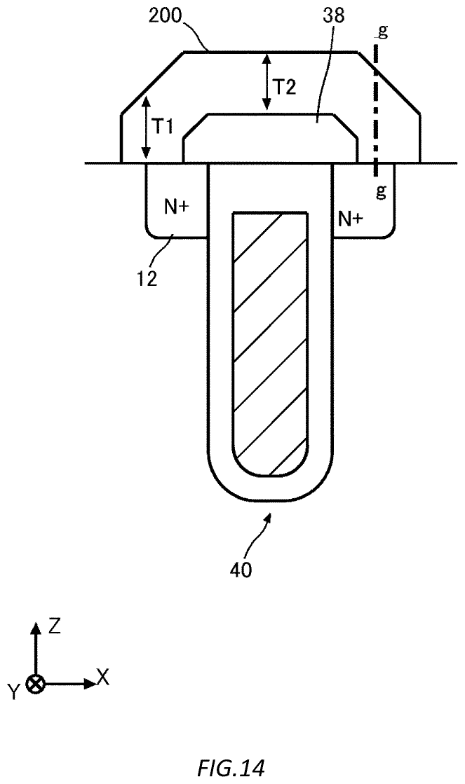

FIG. 14 is an enlarged view of the vicinity of a polysilicon resistance portion 200. A thickness of the polysilicon resistance portion 200 in a depth direction may be 0.1 μm or more and 1 μm or less. Adjusting the thickness of the polysilicon resistance portion 200 can adjust a resistance value between an emitter region 12 and an emitter electrode 52. The thickness of the polysilicon resistance portion 200 may be 0.15 μm or more, or may be 2 μm or more. The thickness of the polysilicon resistance portion 200 may be 0.8 μm or less, may be 0.6 μm or less, or may be 0.3 μm or less.

The thickness of the polysilicon resistance portion 200 in the depth direction may be a shortest distance between the emitter region 12 and the emitter electrode 52. In another example, a thickness T1 in the Z axis direction of a portion stacked on the emitter region 12 may be used as the thickness of the polysilicon resistance portion 200. The thickness T1 may be a minimum thickness of the portion stacked on the emitter region 12. A thickness T2 of a portion stacked on a central position of an interlayer dielectric film 38 in the X axis direction may be used as the thickness of the polysilicon resistance portion 200.

An impurity of the N type may be added to the polysilicon resistance portion 200. That is, an impurity of the same conductivity type as that of the emitter region 12 may be added to the polysilicon resistance portion 200. An impurity of the same element as that of the emitter region 12 may be added to the polysilicon resistance portion 200. As one example, the impurity is phosphorous. Adding the impurity of the N type to the polysilicon resistance portion 200 can suppress influence on each other's characteristic even if the impurity diffuses between the polysilicon resistance portion 200 and the emitter region 12.

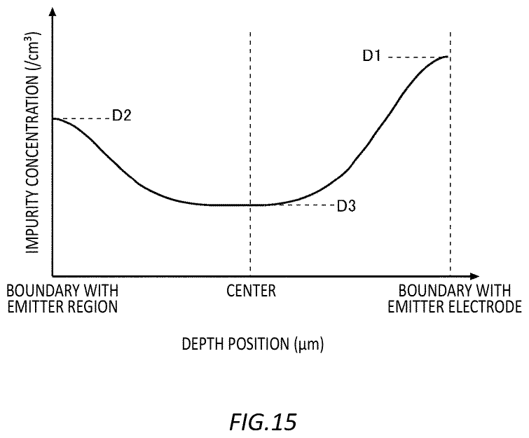

FIG. 15 illustrates one example of an impurity concentration distribution of the polysilicon resistance portion 200 on a line g-g in FIG. 14. The line g-g is a line parallel to a depth direction of the polysilicon resistance portion 200. The depth direction of the polysilicon resistance portion 200 may be the Z axis direction. In another example, the depth direction of the polysilicon resistance portion 200 may be a direction of a straight line which passes through the polysilicon resistance portion 200 and connects an emitter region 12 and an emitter electrode 52 with the shortest distance.

In the polysilicon resistance portion 200, an impurity concentration D1 of a region in contact with the emitter electrode 52 and an impurity concentration D2 of a region in contact with the emitter region 12 may be both higher than an impurity concentration D3 at a center of the polysilicon resistance portion 200 in the depth direction. Such a configuration can prevent a contact resistance between the polysilicon resistance portion 200 and the emitter electrode 52 or the like from becoming too high. Implanting an impurity from above the polysilicon resistance portion 200 can make the impurity concentration D1 relatively high. In addition, performing heat treatment after forming the polysilicon resistance portion 200 can diffuse an impurity of the emitter region 12 into the polysilicon resistance portion 200 and make the impurity concentration D2 relatively high.

The impurity concentration D3 of the polysilicon resistance portion 200 may be 1×10¹⁴/cm³ or more and 1×10¹⁵/cm³ or less. The impurity concentrations D1, D2, and D3 may be all 1×10¹⁴/cm³ or more and 1×10¹⁵/cm³ or less, and an average impurity concentration of the polysilicon resistance portion 200 in the depth direction may be 1×10¹⁴/cm³ or more and 1×10¹⁵/cm³ or less. Adjusting an impurity concentration of the polysilicon resistance portion 200 can adjust a resistance value of the polysilicon resistance portion 200.

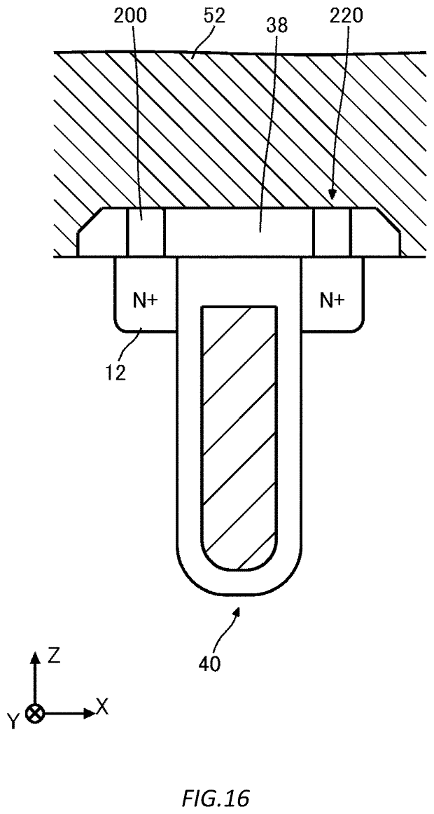

FIG. 16 illustrates another example of a polysilicon resistance portion 200. FIG. 16 is an enlarged cross-sectional view of the vicinity of a gate trench portion 40. The polysilicon resistance portion 200 in the present example is provided inside a contact hole 220 provided in an interlayer dielectric film 38. Structures other than the polysilicon resistance portion 200 and the interlayer dielectric film 38 are similar to those of the semiconductor device 100 according to any of the aspects described with reference to FIG. 1 to FIG. 15.

The contact hole 220 is provided between an emitter region 12 and an emitter electrode 52. The contact hole 220 is provided for each emitter region 12. A width of one contact hole 220 in the X axis direction may be smaller than, may be the same as, or may be greater than, a width of one emitter region 12 in the X axis direction. A width of one contact hole 220 in the Y axis direction may be smaller than, may be the same as, or may be greater than, a width of one emitter region 12 in the Y axis direction. Adjusting a size of the contact hole 220 in the XY plane can adjust a resistance value of the polysilicon resistance portion 200 in a depth direction.

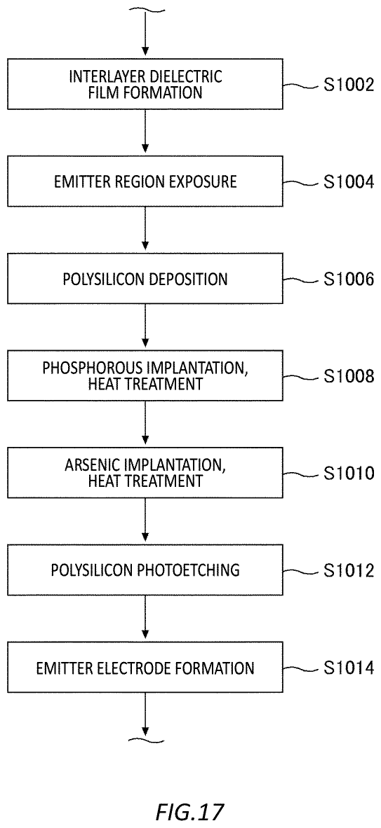

FIG. 17 illustrates some processes in a method for manufacturing a semiconductor device 100. The manufacturing method in the present example has an interlayer dielectric film formation step S1002, an emitter region exposure step S1004, a polysilicon deposition step S1006, a first impurity implantation step S1008, a second impurity implantation step S1010, an etching step S1012, and an emitter electrode formation step S1014. Before the interlayer dielectric film formation step S1002, a dopant is implanted into a semiconductor substrate 10 to form each region such as an emitter region 12. In addition, before the interlayer dielectric film formation step S1002, a trench portion is formed.

In the interlayer dielectric film formation step S1002, an interlayer dielectric film 38 is formed on an upper surface 21 of the semiconductor substrate 10. In the interlayer dielectric film formation step S1002, a dielectric film such as PSG may be deposited on an entirety of the upper surface 21.

In the emitter region exposure step S1004, part of the interlayer dielectric film 38 is removed to expose the emitter region 12. In the emitter region exposure step S1004, the interlayer dielectric film 38 may be dry etched or wet etched, or the interlayer dielectric film 38 may be ground by a method such as CMP.

In the polysilicon deposition step S1006, a polysilicon film is deposited above the upper surface 21 of the semiconductor substrate 10 and the interlayer dielectric film 38 by a CVD method or the like. In the first impurity implantation step S1008, an impurity such as phosphorous is implanted into an entirety of an upper surface of the polysilicon film. Heat treatment may be performed after the impurity is implanted, to diffuse the impurity in a depth direction of the polysilicon film. In the heat treatment in the first impurity implantation step S1008, the semiconductor substrate 10 may be put into an annealing furnace to heat an entirety of the semiconductor substrate 10.

In the second impurity implantation step S1010, an impurity such as arsenic is implanted into the vicinity of the upper surface of the polysilicon film. The polysilicon film may be heat treated after the impurity is implanted. In the second impurity implantation step S1010, the polysilicon film may be heated by Rapid Thermal Anneal (RTA). A heat treatment time in the second impurity implantation step S1010 may be shorter than a heat treatment time in the first impurity implantation step S1008. Such a processing can increase an impurity concentration in the vicinity of an upper surface of the polysilicon resistance portion 200 as shown in FIG. 15.

In the etching step S1012, a photolithographic processing and an etching processing are performed on the polysilicon film. As a result, the polysilicon resistance portion 200 having a predetermined shape is formed. In the emitter electrode formation step S1014, an emitter electrode 52 is formed so as to cover the upper surface 21 of the semiconductor substrate 10, the interlayer dielectric film 38, and the polysilicon resistance portion 200. In the emitter electrode formation step S1014, the emitter electrode 52 may be formed by a sputtering method or the like. After the emitter electrode formation step S1014, there may be a process of forming another structure of the semiconductor device 100.

The semiconductor device 100 described with reference to FIG. 1 to FIG. 15 can be manufactured through the processes shown in FIG. 17. When the trench contact portion 210 shown in FIG. 12A is formed, a concave portion of the trench contact portion 210 may be formed between the etching step S1012 and the emitter electrode formation step S1014. In the process, the semiconductor substrate 10 and a dummy trench portion 30 may be etched at the same time to form the concave portion.

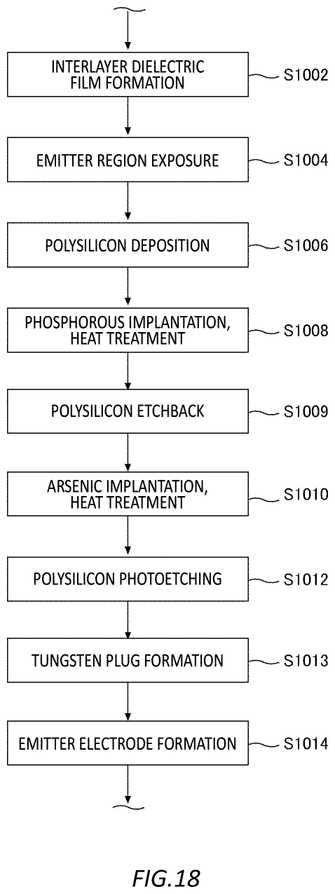

FIG. 18 illustrates another example of a method for manufacturing a semiconductor device 100. In the manufacturing method in the present example, the semiconductor device 100 having the structure shown in FIG. 16 is manufactured. An interlayer dielectric film formation step S1002 is similar to that in the example shown in FIG. 17.

In an emitter region exposure step S1004, part of an interlayer dielectric film 38 is removed to form a contact hole 220, and an emitter region 12 is exposed. In the emitter region exposure step S1004, the contact hole 220 may be formed through etching.

A polysilicon deposition step S1006, a first impurity implantation step S1008, and a second impurity implantation step S1010 are similar to those in the example shown in FIG. 17. An etchback step S1009 may be performed between the first impurity implantation step S1008 and the second impurity implantation step S1010. In the etchback step S1009, at least a polysilicon film present above the contact hole 220 is etched and removed. The etchback step S1009 may remove the polysilicon film present at a place other than the inside of the contact hole 220.

After the second implantation step S1010, an etching step S1012 is performed. The etching step S1012 is similar to that in the example shown in FIG. 17. When the etchback step S1009 is performed, the etching step S1012 may remove the polysilicon film which has not been completely removed in the etchback step S1009.

An emitter electrode formation step S1014 and subsequent steps are similar to those in the example shown in FIG. 17. A plug formation step S1013 may be performed between the etching step S1012 and the emitter electrode formation step S1014. The plug formation step S1013 forms a tungsten plug which connects an emitter electrode 52 and a contact region 15 or a base region 14. The tungsten plug may be embedded inside from an upper surface 21 of a semiconductor substrate 10. When the contact region 15 or the base region 14 is covered with the interlayer dielectric film 38, the tungsten plug may be formed in the contact hole formed in the interlayer dielectric film 38.

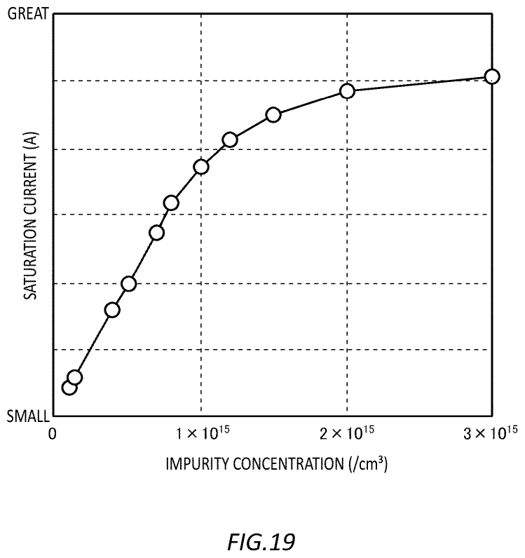

FIG. 19 illustrates a relationship between an impurity concentration of a polysilicon resistance portion 200 and a saturation current flowing through a semiconductor device 100. As shown in FIG. 19, decreasing the impurity concentration of the polysilicon resistance portion 200 and increasing a resistance value of the polysilicon resistance portion 200 decreases the saturation current. A total emitter width Z of a contact between a gate trench portion 40 and an emitter region 12 can be increased according to an amount of decrease in the saturation current.

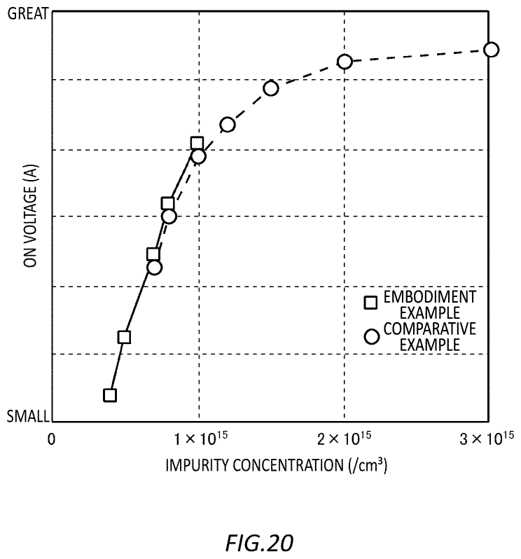

FIG. 20 illustrates relationships between an impurity concentration of a polysilicon resistance portion 200 and an ON voltage of a semiconductor device 100. In the present example, a saturation current is set to approximately 540A (175 degrees C.). FIG. 20 indicates, by a solid line, an embodiment example in which an emitter region 12 has a longitudinal side in the Y axis direction, and indicates, by a dashed line, a comparative example in which an emitter region 12 has a longitudinal side in the X axis direction. In the embodiment example, a total emitter width Z can be increased. Therefore, the impurity concentration of the polysilicon resistance portion 200 can be decreased to decrease the ON voltage. As shown in FIG. 19 and FIG. 20, the semiconductor device 100 according to the embodiment example can achieve a characteristic of a low ON voltage and a low saturation current.

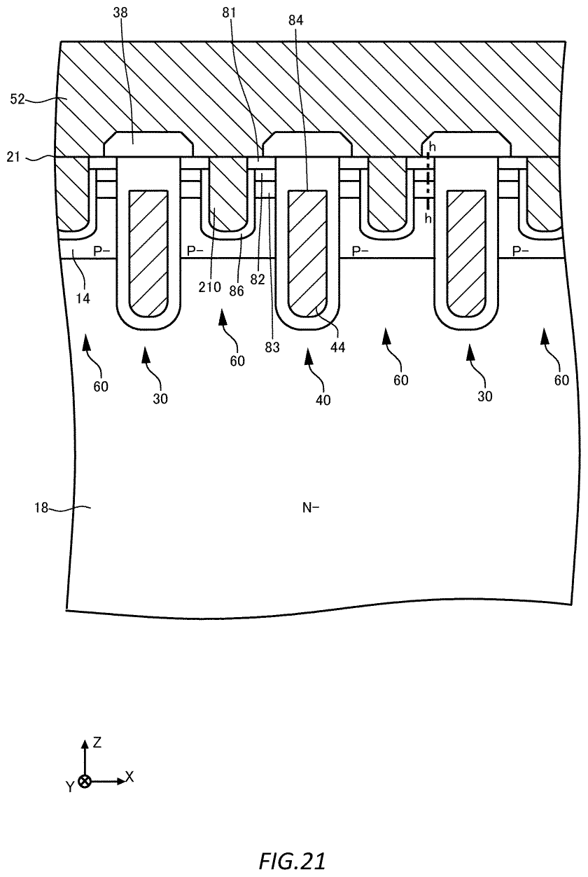

FIG. 21 is a cross-sectional view showing another configuration of a semiconductor device 100. FIG. 21 shows the XZ cross section having the same position in the Y axis direction as that of the cross section a-a. Note that, however, the cross section in FIG. 21 includes one gate trench portion 40 and dummy trench portions 30 arranged on both sides of the gate trench portion 40. In addition, in the cross section in FIG. 21, a configuration on a lower surface 23 side of a semiconductor substrate 10 is omitted. Structures other than the cross section may be similar to those of the semiconductor device 100 according to any of the aspects described with reference to FIG. 1 to FIG. 20.

The semiconductor device 100 in the present example is different from the semiconductor device 100 described with reference to FIG. 1 to FIG. 20 in that it does not include a polysilicon resistance portion 200. An emitter electrode 52 is provided in a region where the polysilicon resistance portion 200 is provided in FIG. 1 to FIG. 20. The semiconductor device 100 in the present example is different from the semiconductor device 100 described with reference to FIG. 1 to FIG. 20 in a structure of an emitter region 12. The emitter region 12 in the present example has a first emitter portion 81 of an N+ type and a second emitter portion 82 of an N type.

The emitter region 12 may further have a third emitter portion 83 of the N+ type. In FIG. 21, a reference numeral of the emitter region 12 is omitted. The semiconductor device 100 in the present example may further include a trench contact portion 210 and a high concentration region 86. Other structures are similar to those of the semiconductor device 100 described with reference to FIG. 1 to FIG. 20.

A mesa portion 60 in the present example has the emitter region 12 for each trench portion. That is, it has the emitter region 12 for each of the dummy trench portions 30 and the gate trench portion 40. In another example, the mesa portion 60 may not have the emitter region 12 in contact with a dummy trench portion 30.

The first emitter portion 81 is provided in contact with an upper surface 21 of the semiconductor substrate 10. The first emitter portion 81 may be in contact with the emitter electrode 52 at the upper surface 21 of the semiconductor substrate 10. The first emitter portion 81 may be in contact with a side surface of the trench portion.

The second emitter portion 82 is provided in contact with the first emitter portion 81 under the first emitter portion 81. The second emitter portion 82 is a region of the N type having a lower doping concentration than the first emitter portion 81. The second emitter portion 82 may be in contact with the side surface of the trench portion. The second emitter portion 82 in the present example is not in contact with the emitter electrode 52.

The mesa portion 60 in the present example is configured such that a current flowing between the second emitter portion 82 and the emitter electrode 52 passes through the first emitter portion 81. That is, in the mesa portion 60, at least one of the first emitter portion 81, a dielectric film, or a region of a P type is arranged in each path connecting the second emitter portion 82 and the emitter electrode 52. In addition, the mesa portion 60 in the present example is configured such that a current flowing between the first emitter portion 81 and a base region 14 passes through the second emitter portion 82. That is, in the mesa portion 60, at least one of the second emitter portion 82, a dielectric film, or a region of a P type is arranged in each path connecting the first emitter portion 81 and the base region 14.

The second emitter portion 82 in the present example has a lower doping concentration than the first emitter portion 81. This increases a resistance value of the second emitter portion 82. In addition, the current flowing between the first emitter portion 81 and the base region 14 passes through the second emitter portion 82. Therefore, the second emitter portion 82 in the present example functions as a resistance portion. As a result, a saturation current flowing through a MOS structure can be suppressed similarly to the semiconductor device 100 in FIG. 1 to FIG. 20. In addition, a total emitter width is increased and an ON voltage is decreased by providing the emitter region 12 having a longitudinal side in the Y axis direction. This can achieve both a low saturation current and a low ON voltage. According to the present example, the resistance portion can be provided without using an additional film such as the polysilicon resistance portion 200.

The third emitter portion 83 is provided in contact with the second emitter portion 82 under the second emitter portion 82. The third emitter portion 83 is a region of the N+ type having a higher doping concentration than the second emitter portion 82. The third emitter portion 83 may have a lower doping concentration than the first emitter portion 81. The third emitter portion 83 may be in contact with the side surface of the trench portion. The third emitter portion 83 in the present example is not in contact with the emitter electrode 52.

Providing the third emitter portion 83 can prevent the second emitter portion 82 from coming into direct contact with the region of the P type. Therefore, it is possible to suppress diffusion of a dopant in the region of the P type into the second emitter portion 82 with a low concentration and to control a length of the second emitter portion 82 in the depth direction with high precision. Therefore, it is possible to suppress a variation in the resistance value in the second emitter portion 82.

An upper end 84 of a gate conductive portion 44 of the gate trench portion 40 is preferably arranged facing the third emitter portion 83. The upper end 84 of the gate conductive portion 44 may refer to an upper end at side walls facing the mesa portion 60. The upper end 84 and the third emitter portion 83 facing each other means that the upper end 84 is arranged between an upper end position and a lower end position of the third emitter portion 83 in the Z axis direction. An upper end and a lower end of the third emitter portion 83 may refer to an upper end and a lower end at a portion in contact with a side wall of the gate trench portion 40.

When an ON voltage is applied to the gate conductive portion 44, electrons are attracted to a region facing the gate conductive portion 44 in a boundary portion with the trench portion in the mesa portion 60. When the second emitter portion 82 and the gate conductive portion 44 are arranged facing each other, electrons are also attracted to a boundary portion of the second emitter portion 82. Since the second emitter portion 82 has a low doping concentration, the resistance value in the boundary portion may vary due to the attracted electrons. In contrast, arranging the third emitter portion 83 so as to face the upper end 84 of the gate conductive portion 44 can suppress a fluctuation in the resistance value in the boundary portion of the second emitter portion 82. In addition, since the third emitter portion 83 has a high doping concentration, even if electrons are attracted to a boundary portion of the third emitter portion 83, a fluctuation in the resistance value in the boundary portion is extremely small.

The trench contact portion 210 is provided from the upper surface 21 of the semiconductor substrate 10 to a position lower than that of an upper end of the base region 14. The trench contact portion 210 is formed of a conductive material. The trench contact portion 210 may be formed of the same material as or a different material from that of the emitter electrode 52 above the semiconductor substrate 10. For example, the trench contact portion 210 may contain tungsten.

The high concentration region 86 is a region of a P+ type having a higher concentration than the base region 14. A doping concentration of the high concentration region 86 may be the same as a doping concentration of a contact region 15. The doping concentration of the high concentration region 86 may be more than or equal to 10 times, may be more than or equal to 50 times, or may be more than or equal to 100 times, a doping concentration of the base region 14. The high concentration region 86 is in contact with the trench contact portion 210. The high concentration region 86 is provided at least between the trench contact portion 210 and the base region 14. The high concentration region 86 in the present example is in contact with a lower end and side walls of the trench contact portion 210. The high concentration region 86 in the present example is not in contact with an upper end at the side walls of the trench contact portion 210.

The first emitter portion 81 in the present example is in contact with the trench contact portion 210. This can decrease a connection resistance between the emitter electrode 52 and the first emitter portion 81. The first emitter portion 81 may be in contact with an upper end of the high concentration region 86.

The second emitter portion 82 is not in contact with the trench contact portion 210. The dielectric film or the region of the P type may be provided between the second emitter portion 82 and the trench contact portion 210. In the present example, the high concentration region 86 of the P type is provided between the second emitter portion 82 and the trench contact portion 210. Such a configuration can prevent a current from flowing between the emitter electrode 52 and the second emitter portion 82 through a path other than the first emitter portion 81.

The third emitter portion 83 is not in contact with the trench contact portion 210. The dielectric film or the region of the P type may be provided between the third emitter portion 83 and the trench contact portion 210. In the present example, the high concentration region 86 of the P type is provided between the third emitter portion 83 and the trench contact portion 210. Such a configuration can prevent a current having passed through a channel of the base region 14 from flowing to the emitter electrode 52 without passing through the second emitter portion 82.

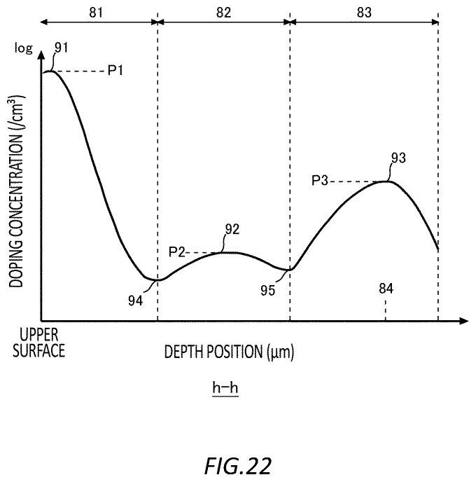

FIG. 22 illustrates one example of a doping concentration distribution on a line h-h in FIG. 21. The line h-h is a line parallel to the Z axis, which passes through a first emitter portion 81, a second emitter portion 82, and a third emitter portion 83.

The first emitter portion 81 in the present example has a peak 91 of the doping concentration distribution in a depth direction. A peak of the doping concentration distribution is a mountain-like portion where a doping concentration exhibits a local maximum value at a local maximum. A doping concentration at the local maximum of the peak is defined as the doping concentration of the peak. A doping concentration of the peak 91 is defined as P1. It should be noted that a doping concentration of the first emitter portion 81 may continuingly increase from a boundary with the second emitter portion 82 to an upper surface 21 of a semiconductor substrate 10. In this case, the doping concentration of the first emitter portion 81 at the upper surface 21 is defined as P1.

The second emitter portion 82 in the present example has a peak 92 of the doping concentration distribution in the depth direction. A doping concentration of the peak 92 is defined as P2. Between the first emitter portion 81 and the second emitter portion 82, a valley portion 94 where the doping concentration exhibits a local minimum value is defined as a boundary between the first emitter portion 81 and the second emitter portion 82.

The third emitter portion 83 in the present example has a peak 93 of the doping concentration distribution in the depth direction. A doping concentration of the peak 93 is defined as P3. Between the second emitter portion 82 and the third emitter portion 83, a valley portion 95 where the doping concentration exhibits a local minimum value is defined as a boundary between the second emitter portion 82 and the third emitter portion 83.

As described above, the concentration P2 of the peak 92 of the second emitter portion 82 is lower than the concentration P1 of the peak 91 of the first emitter portion 81. The concentration P2 may be less than or equal to 1/100 times, or may be less than or equal to 1/1000 times, the concentration P1. The concentration P2 may be less than or equal to 10 times, or may be less than or equal to five times, a doping concentration of the valley portion 94. The concentration P2 is higher than a doping concentration of a drift region 18. The concentration P2 may be less than or equal to 100 times, may be less than or equal to 10 times, or may be less than or equal to five times, the doping concentration of the drift region 18. Adjusting the concentration P2 can adjust a resistance value in a resistance portion.

A length of the second emitter portion 82 in the depth direction may be 2 μm or less. The length may be 1.5 μm or less, or may be 1 μm or less. The length may be 0.1 μm or more, or may be 0.5 μm or more. A length of an entirety of an emitter region 12 in the depth direction may be 3 μm or less.

The emitter region 12 in the present example can be formed by implanting dopant ions of an N type at respective positions of the peak 91, the peak 92, and the peak 93. A length of the second emitter portion 82 can be adjusted by a depth position where the peak 91 and the peak 93 are formed. Adjusting the length of the second emitter portion 82 can adjust the resistance value in the resistance portion.

As described above, the concentration P3 of the peak 93 of the third emitter portion 83 is higher than the concentration P2 of the peak 92 of the second emitter portion 82. The concentration P3 may be more than or equal to 10 times, may be more than or equal to 50 times, or may be more than or equal to 100 times, the concentration P2. The concentration P3 of the peak 93 of the third emitter portion 83 may be less than or equal to the concentration P1 of the peak 91 of the first emitter portion 81. The concentration P3 may be less than or equal to ½ times, may be less than or equal to ⅕ times, or may be less than or equal to 1/10 times, the concentration P1.

As described with reference to FIG. 21, a depth position of an upper end 84 of a gate conductive portion 44 is included in a depth range where the third emitter portion 83 is provided. The upper end 84 may be provided in a range of a full width at half maximum of the peak 93. The range of the full width at half maximum of the peak 93 is a range where the doping concentration is more than or equal to half the P3 at the peak 93.

A length of the third emitter portion 83 in the depth direction may be 0.4 μm or more. As a result, even if the depth position of the upper end 84 of the gate conductive portion 44 varies due to a variation in manufacturing or the like, the upper end 84 can be arranged at a position facing the third emitter portion 83. The length of the third emitter portion 83 in the depth direction may be 1 μm or less. The third emitter portion 83 only needs to be able to absorb a variation in the depth position of the upper end 84. Setting the length of the third emitter portion 83 to 1 μm or less can decrease a total length of the emitter region 12.

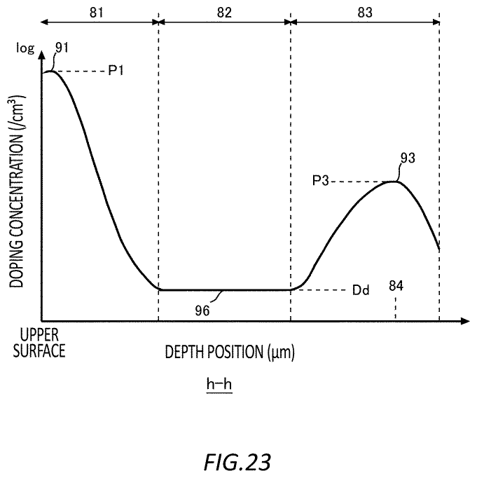

FIG. 23 illustrates another example of a doping concentration distribution on the line h-h. The doping concentration distribution in the present example is different from that in the example shown in FIG. 22 in a distribution in a second emitter portion 82. The distribution in a first emitter portion 81 and a third emitter portion 83 is similar to that in the example shown in FIG. 22.

The second emitter portion 82 in the present example has a flat portion 96 where the doping concentration distribution in a depth direction is flat. For example, the flat portion 96 is a portion where a maximum value of a doping concentration is less than or equal to twice a minimum value of the doping concentration. A length of the flat portion 96 in the depth direction may be 0.1 μm or more, or may be 0.5 μm or more.

The minimum value of the doping concentration of the flat portion 96 may be less than or equal to 10 times, may be less than or equal to five times, or may be less than or equal to twice, a doping concentration Dd. The minimum value of the doping concentration of the flat portion 96 may be the same as the doping concentration Dd of a drift region 18. In the present example, dopant ions of an N type are not implanted into the second emitter portion 82.

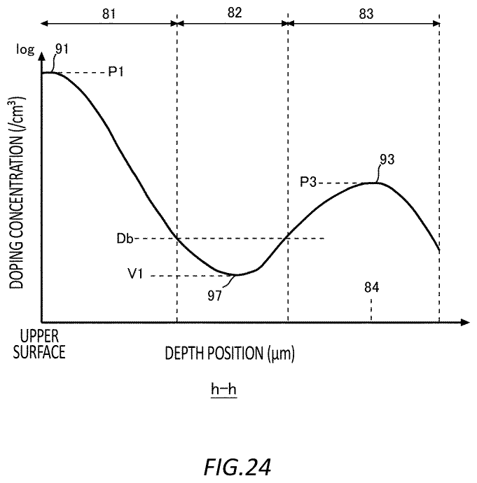

FIG. 24 illustrates another example of a doping concentration distribution on the line h-h. The doping concentration distribution in the present example is different from that in the example shown in FIG. 22 in a distribution in a second emitter portion 82. The distribution in a first emitter portion 81 and a third emitter portion 83 is similar to that in the example shown in FIG. 22.

The second emitter portion 82 in the present example has a valley portion 97 where a doping concentration exhibits a local minimum value in a depth direction. The local minimum value of the doping concentration in the valley portion 97 is defined as V1. The concentration V1 may be less than or equal to 100 times, may be less than or equal to 50 times, may be less than or equal to 10 times, or may be less than or equal to five times, a doping concentration Dd of a drift region 18. The concentration V1 may be the same as the concentration Dd. In the present example, dopant ions of an N type are not implanted into the second emitter portion 82. The valley portion 97 in the vicinity of a boundary between a first peak 91 and a third peak 93 functions as the second emitter portion 82.

The doping concentration at each end of the second emitter portion 82 in the depth direction is defined as Db. The concentration Db may be 10 times the concentration V1, may be five times the concentration V1, or may be another value. A length of the second emitter portion 82 in the depth direction is similar to that in the example shown in FIG. 22 or FIG. 23.

The second emitter portion 82 has any of the peak 92 shown in FIG. 22, the flat portion 96 shown in FIG. 23, or the valley portion 97 shown in FIG. 24. The second emitter portion 82 may be provided with several of the peak 92, the flat portion 96, and the valley portion 97.

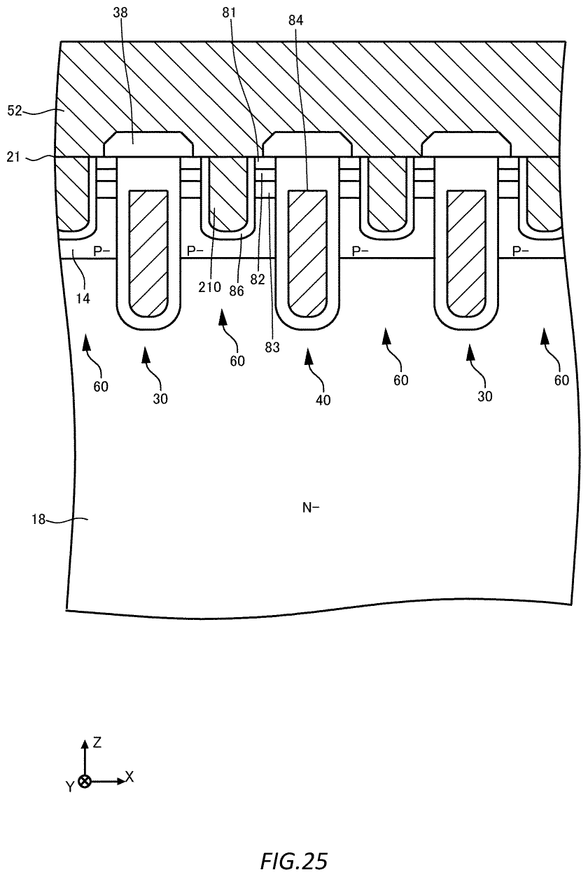

FIG. 25 is a cross-sectional view showing another configuration of a semiconductor device 100. The semiconductor device 100 in the present example is different from that in the example shown in FIG. 21 in a structure of a high concentration region 86. Other structures are similar to those in the example shown in FIG. 21.

The high concentration region 86 in the present example is also provided between a first emitter portion 81 and a trench contact portion 210. The first emitter portion 81 in the present example is not in contact with the trench contact portion 210. According to the present example, even with a variation in a range where the high concentration region 86 is formed, it is possible to suppress connection between a second emitter portion 82 and the trench contact portion 210.

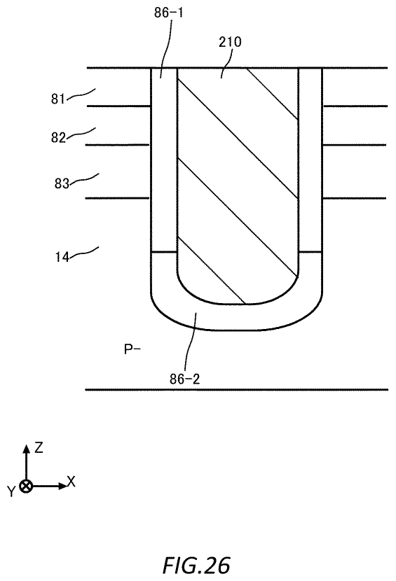

FIG. 26 illustrates another structure example of a high concentration region 86. In the present example, a first high concentration region 86-1 and a second high concentration region 86-2 are provided. Other structures are similar to those in the example shown in FIG. 25. The first high concentration region 86-1 and the second high concentration region 86-2 are both regions of a P type having a higher concentration than a base region 14. The first high concentration region 86-1 is a region having a lower concentration than the second high concentration region 86-2.

The first high concentration region 86-1 is provided between a trench contact portion 210, and a second emitter portion 82 and a third emitter portion 83. The first high concentration region 86-1 in the present example is also provided between the trench contact portion 210 and a first emitter portion 81. As in the example shown in FIG. 21, when the first emitter portion 81 is in contact with the trench contact portion 210, the first high concentration region 86-1 may not be provided between the trench contact portion 210 and the first emitter portion 81.

The second high concentration region 86-2 is provided in contact with a lower end of the trench contact portion 210. The second high concentration region 86-2 may be provided so as to cover an entirety of a lower surface of the trench contact portion 210. The lower surface of the trench contact portion 210 may refer to a portion of an outer surface of the trench contact portion 210 where an angle between a normal direction and a downward direction on the Z axis is 45 degrees or less.

A high concentration of the second high concentration region 86-2 can make a small contact resistance between the trench contact portion 210 and the base region 14. A low concentration of the first high concentration region 86-1 can suppress diffusion of a dopant of the P type in the first high concentration region 86-1 into the second emitter portion 82. Therefore, it is possible to adjust a doping concentration in the second emitter portion 82 with high precision and to adjust a resistance value of a resistance portion with high precision.

A doping concentration of the first high concentration region 86-1 may be less than or equal to 0.2 times, may be less than or equal to 0.1 times, or may be less than or equal to 0.05 times, a doping concentration of the second high concentration region 86-2. A maximum value of the doping concentration in the second high concentration region 86-2 may be used as the doping concentration of the second high concentration region 86-2.

The first high concentration region 86-1 and the second high concentration region 86-2 may be formed by forming a groove portion for forming the trench contact portion 210 in the semiconductor substrate 10 and implanting dopant ions of the P type from the groove portion. The doping concentrations of the first high concentration region 86-1 and the second high concentration region 86-2 can be adjusted by adjusting an implantation angle and a dose amount of the dopant ions. The doping concentrations of the first high concentration region 86-1 and the second high concentration region 86-2 may be adjusted by implanting the dopant ions multiple times changing at least one of the implantation angle or the dose amount of the dopant ions.

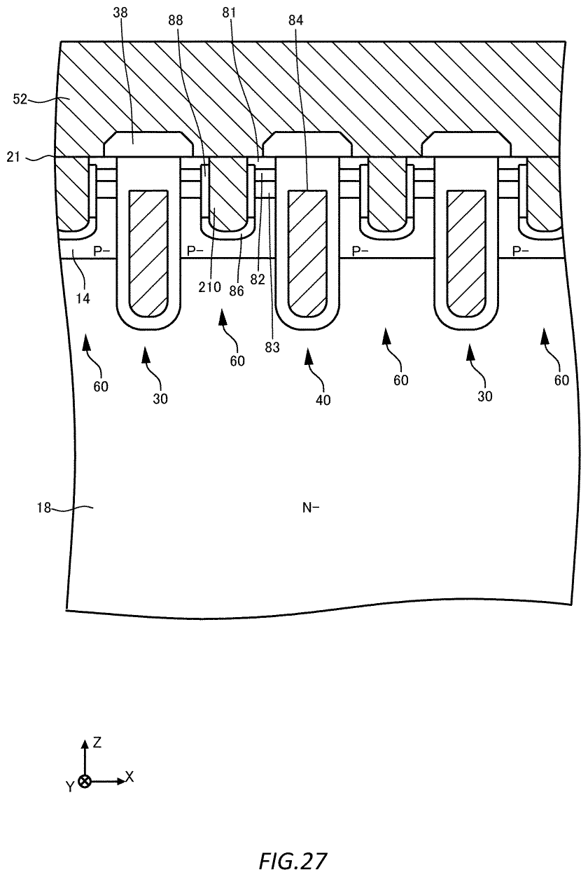

FIG. 27 is a cross-sectional view showing another configuration of a semiconductor device 100. The semiconductor device 100 in the present example is different from that in the example shown in FIG. 21 in that it has a contact dielectric film 88 in stead of part of a high concentration region 86. Other structures are similar to those in the example shown in FIG. 21.

The contact dielectric film 88 may be a film obtained by oxidizing or nitriding a semiconductor substrate 10. A position and a range where the contact dielectric film 88 is provided may be similar to a position and a range where the first high concentration region 86-1 described with reference to FIG. 26 is provided. The position and the range where the high concentration region 86 is provided in the present example may be similar to a position and a range where the second high concentration region 86-2 described with reference to FIG. 26 is provided.

The contact dielectric film 88 in the present example is provided between a trench contact portion 210, and a second emitter portion 82 and a third emitter portion 83. In the present example, a first emitter portion 81 is in contact with the trench contact portion 210. The contact dielectric film 88 may not be provided between the first emitter portion 81 and the trench contact portion 210.

A position of an upper end of the contact dielectric film 88 may be the same as a position of an upper end of the second emitter portion 82. The position of the upper end of the contact dielectric film 88 may be located above the upper end of the second emitter portion 82. This can prevent the second emitter portion 82 from coming into contact with the trench contact portion 210.

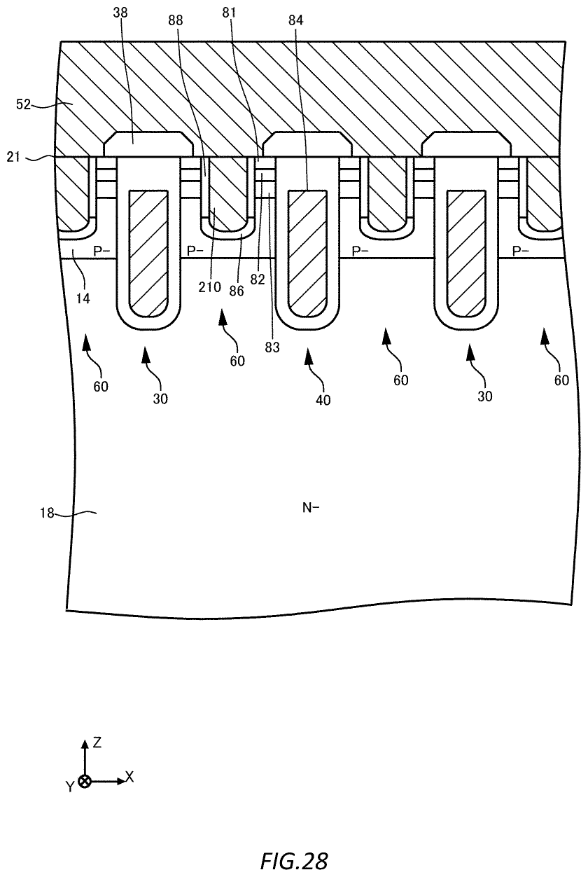

FIG. 28 is a cross-sectional view showing another configuration of a semiconductor device 100. The semiconductor device 100 in the present example is different from that in the example shown in FIG. 27 in a structure of a contact dielectric film 88. Other structures are similar to those in the example shown in FIG. 27. The contact dielectric film 88 in the present example is also provided between a first emitter portion 81 and a trench contact portion 210. The first emitter portion 81 in the present example is not in contact with the trench contact portion 210.

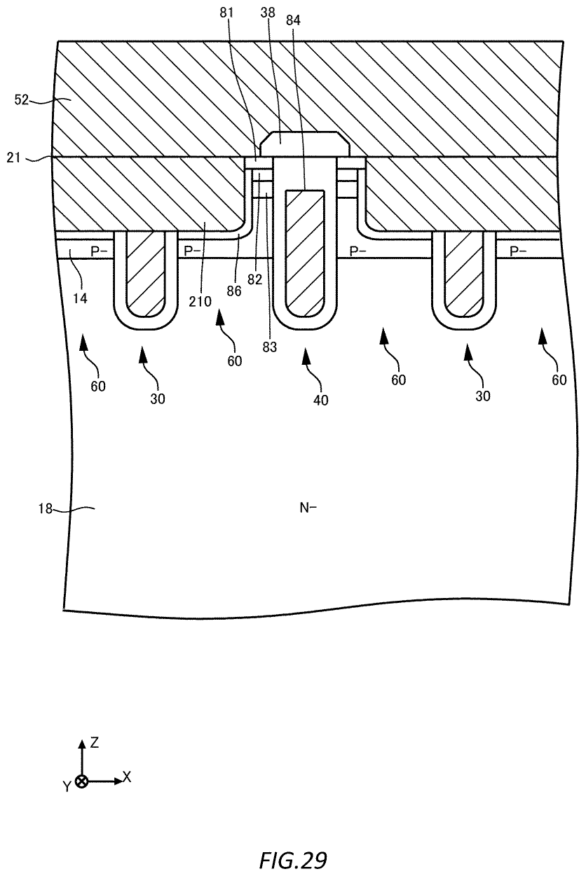

FIG. 29 is a cross-sectional view showing another example of a semiconductor device 100. A cross section in the present example shows a position and a range similar to those in the example in FIG. 21. In the present example, a trench contact portion 210 is provided across two mesa portions 60 arranged on both sides of a dummy trench portion 30 in the X axis direction. The trench contact portion 210 in the present example may be formed of the same material as that of an emitter electrode 52. A structure between the trench contact portion 210 and a gate trench portion 40 is similar to that according to any of the aspects described with reference to FIG. 21 to FIG. 28.

The dummy trench portion 30 is formed at a bottom surface of the trench contact portion 210. A dummy conductive portion 34 of the dummy trench portion 30 is connected to the trench contact portion 210. This allows application of an emitter potential to the dummy conductive portion 34. A high concentration region 86 is provided in at least part of a region of the bottom surface and a side surface of the trench contact portion 210 which is not connected to the dummy trench portion 30. The high concentration region 86 may be provided or may not be provided between a first emitter portion 81 and the trench contact portion 210.

In the example shown in FIG. 29, one dummy trench portion 30 is provided at a bottom surface of one trench contact portion 210. In another example, a plurality of dummy trench portions 30 arranged in the X axis direction may be provided at the bottom surface of one trench contact portion 210. The trench contact portion 210 may be provided in common for two or more dummy trench portions 30 which are arranged to be sandwiched between two gate trench portions 40 in the X axis direction. Such a structure allows easy provision of the trench contact portion 210 even if an interval between trench portions is decreased.

A depth position of a lower end of the dummy trench portion 30 provided at the bottom surface of the trench contact portion 210 may be the same as or different from a depth position of a lower end of a gate trench portion 40. The lower end of the dummy trench portion 30 may be arranged below the lower end of the gate trench portion 40. The dummy trench portion 30 provided at the bottom surface of the trench contact portion 210 may have a structure similar to that in the example shown in FIG. 12B, or may have a structure similar to that in the example shown in FIG. 12C.

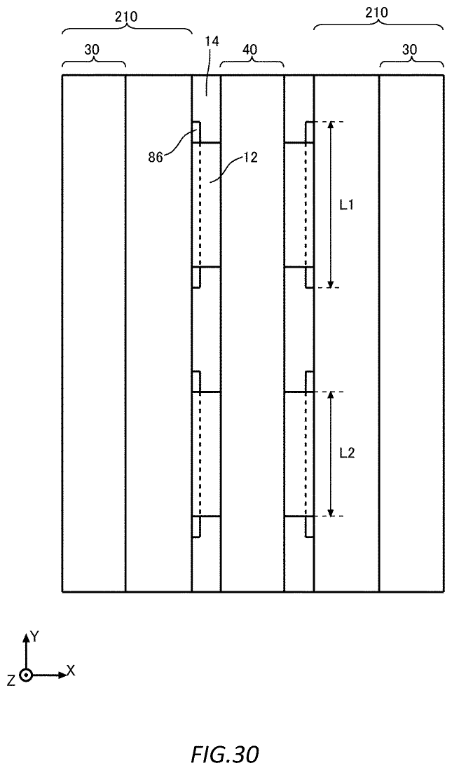

FIG. 30 illustrates an arrangement example of a high concentration region 86 and an emitter region 12 in a top view. In the present example, a plurality of emitter regions 12 are discretely arranged in the Y axis direction. A region of a P type such as a base region 14 is provided in a region of an upper surface 21 of a semiconductor substrate 10 where the emitter region 12 is not provided.

In the present example, a plurality of high concentration regions 86 are discretely arranged in the Y axis direction. Each of the high concentration regions 86 is arranged so as to overlap the emitter region 12. A length L1 of the high concentration region 86 in the Y axis direction may be greater than a length L2 of the emitter region 12 in the Y axis direction.

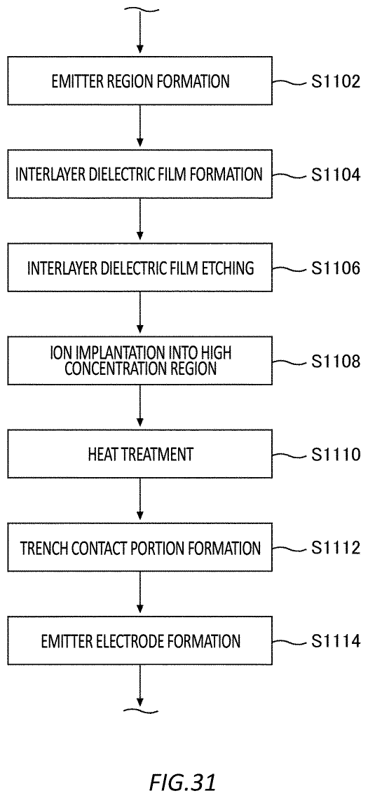

FIG. 31 illustrates some processes in the method for manufacturing the semiconductor device 100 described with reference to FIG. 21 to FIG. 30. A manufacturing method in the present example has an emitter region formation step S1102, an interlayer dielectric film formation step S1104, an etching step S1106, an ion implantation step S1108, a heat treatment step S1110, a contact portion formation step S1112, and an emitter electrode formation step S1114. Before the emitter region formation step S1102 or the interlayer dielectric film formation step S1104, a trench portion may be formed.

In the emitter region formation step S1102, the emitter region 12 described with reference to FIG. 21 to FIG. 30 is formed. The emitter region 12 has a first emitter portion 81 and a second emitter portion 82. The emitter region 12 may further have a third emitter portion 83. In the emitter region formation step S1102, a plurality of emitter portions are formed by implanting dopant ions of an N type at different depths. After the dopant ions are implanted, a semiconductor substrate 10 may be heat treated.

In the interlayer dielectric film formation step S1104, an interlayer dielectric film 38 is formed on an upper surface 21 of the semiconductor substrate 10. In the interlayer dielectric film formation step S1002, a dielectric film such as PSG may be deposited on an entirety of the upper surface 21.

In the etching step S1106, part of the interlayer dielectric film 38 is removed to expose part of the upper surface 21 of the semiconductor substrate 10. In the etching step S1106, the interlayer dielectric film 38 may be dry etched or wet etched, or the interlayer dielectric film 38 may be ground by a method such as CMP.

In the ion implantation step S1108, dopant ions of a P type are implanted into a region where a high concentration region 86 is to be formed. In the ion implantation step S1108, a groove portion for forming the trench contact portion 210 may be formed to implant the dopant ions into the groove portion. In the heat treatment step S1110, after the dopant ions are implanted into the high concentration region 86, the semiconductor substrate 10 is heat treated. When a contact dielectric film 88 is formed in stead of the high concentration region 86, a step of forming the contact dielectric film 88 may be provided in stead of S1108 and S1110.

In the contact portion formation step S1112, the groove portion provided in the upper surface 21 of the semiconductor substrate 10 is filled with a conductive material to form the trench contact portion 210. In the contact portion formation step S1112, it may be filled with the same material as that of an emitter electrode 52, or may be filled with a material containing tungsten.

In the emitter electrode formation step S1114, the emitter electrode 52 is formed. In the emitter electrode formation step S1114, the emitter electrode 52 may be formed by a sputtering method or the like. After the emitter electrode formation step S1114, there may be a step of forming another structure of the semiconductor device 100.

The semiconductor device 100 described with reference to FIG. 21 to FIG. 30 can be manufactured through the processes shown in FIG. 31. When the trench contact portion 210 shown in FIG. 29 is formed, before the groove portion is filled with the conductive material in the contact portion formation step S1112, a dummy trench portion 30 may be formed at a bottom surface of the groove portion.

While the present invention has been described by way of the embodiments, the technical scope of the present invention is not limited to the scope described in the above-described embodiments. It is apparent to persons skilled in the art that various alterations or improvements can be made to the above-described embodiments. It is apparent from the description of the claims that embodiments added with such alterations or improvements can also be included in the technical scope of the present invention.

It should be noted that the operations, procedures, steps, stages, and the like of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described using phrases such as “first” or “next” in the claims, embodiments, or diagrams for convenience, it does not necessarily mean that the process must be performed in this order.

What is claimed is:

1. A semiconductor device comprising a semiconductor substrate which has an upper surface and a lower surface and is provided with a drift region of a first conductivity type, the semiconductor device comprising:
a gate trench portion having a longitudinal side in a first direction at the upper surface of the semiconductor substrate;
an emitter region of the first conductivity type which is provided to be exposed on the upper surface in the semiconductor substrate, is in contact with the gate trench portion, and has a length in the first direction that is longer than a length in a second direction orthogonal to the first direction;
a base region of a second conductivity type which is provided between the emitter region and the drift region and is in contact with the gate trench portion:
an emitter electrode provided above the upper surface of the semiconductor substrate; and
a resistance portion provided between a lower end of the emitter region and the emitter electrode.

2. The semiconductor device according to claim 1, wherein
the resistance portion is provided between the emitter region and the emitter electrode.

3. The semiconductor device according to claim 2, wherein
the resistance portion has a length in the first direction that is longer than a length in the second direction orthogonal to the first direction.

4. The semiconductor device according to claim 3, wherein
an entirety of the emitter region is covered with the resistance portion.

5. The semiconductor device according to claim 2, further comprising a contact region of the second conductivity type which is provided to be exposed on the upper surface in the semiconductor substrate and is provided in contact with the emitter region at the upper surface, wherein
the resistance portion is arranged so as not to cover at least part of the contact region.

6. The semiconductor device according to claim 5, further comprising a dummy trench portion having a longitudinal side in the first direction at the upper surface of the semiconductor substrate, wherein
the contact region is in contact with the dummy trench portion at the upper surface of the semiconductor substrate, and
the resistance portion is arranged so as not to cover a boundary portion between the contact region and the dummy trench portion.

7. The semiconductor device according to claim 2 further comprising one or more trench portions which are arranged side by side with the gate trench portion in the second direction and have longitudinal sides in the first direction, wherein
the resistance portion is arranged so as to overlap an entirety of the gate trench portion and the emitter region in the second direction and is arranged so as not to overlap the trench portion which is adjacent to the gate trench portion.

8. The semiconductor device according to claim 2, wherein
a plurality of emitter regions including the emitter region are discretely arranged in the first direction, and
a plurality of resistance portions including the resistance portion are discretely arranged in the first direction.

9. The semiconductor device according to claim 2, wherein
a plurality of emitter regions including the emitter region are discretely arranged in the first direction, and
the resistance portion is continuously arranged over two or more emitter regions including the emitter region in the first direction.

10. The semiconductor device according to claim 2, wherein
the resistance portion is a polysilicon resistance portion.

11. The semiconductor device according to claim 10, wherein
an impurity of the first conductivity type is added to the polysilicon resistance portion.

12. The semiconductor device according to claim 10, wherein
an impurity concentration of the polysilicon resistance portion is 1×10¹⁴/cm³ or more and 1×10¹⁵/cm³ or less.

13. The semiconductor device according to claim 10, wherein
in the polysilicon resistance portion, impurity concentrations of a region in contact with the emitter electrode and a region in contact with the emitter region are both higher than an impurity concentration at a center of the polysilicon resistance portion in a depth direction.

14. The semiconductor device according to claim 10, wherein
a thickness of the polysilicon resistance portion in a depth direction is 0.1 μm or more and 1 μm or less.

15. The semiconductor device according to claim 2, further comprising a dummy trench portion which has a longitudinal side in the first direction at the upper surface of the semiconductor substrate and is connected to the emitter electrode, wherein
the emitter region is not in contact with the dummy trench portion.

16. The semiconductor device according to claim 15, wherein
the dummy trench portion has a dummy dielectric film and a dummy conductive portion, and
the dummy conductive portion is connected to the emitter electrode.

17. The semiconductor device according to claim 15, further comprising a trench contact portion which is provided at the upper surface of the semiconductor substrate and is filled with the emitter electrode therein, wherein
the dummy trench portion is provided at a bottom surface of the trench contact portion.

18. The semiconductor device according to claim 17, wherein
two or more dummy trench portions including the dummy trench portion are provided at a bottom surface of one trench contact portion including the trench contact portion.

19. The semiconductor device according to claim 1, wherein the emitter region has:
a first emitter portion in contact with the upper surface of the semiconductor substrate; and
a second emitter portion provided under the first emitter portion and having a lower doping concentration than the first emitter portion, wherein
the second emitter portion has any of: a flat portion where a doping concentration distribution in a depth direction is flat; a valley portion where a doping concentration exhibits a local minimum value in a depth direction; or a peak where a doping concentration exhibits a local maximum value and is lower than that of the first emitter portion in a depth direction, and
the second emitter portion is the resistance portion.

20. The semiconductor device according to claim 19, wherein
the emitter region is provided under the second emitter portion and further has a third emitter portion having a higher doping concentration than the second emitter portion.

21. The semiconductor device according to claim 20, wherein
the third emitter portion has a lower doping concentration than the first emitter portion.

22. The semiconductor device according to claim 20, wherein the gate trench portion has:
a gate conductive portion provided inside the semiconductor substrate; and
a gate dielectric film provided between the gate conductive portion and the semiconductor substrate, wherein
an upper end of the gate conductive portion is arranged facing the third emitter portion.

23. The semiconductor device according to claim 20, wherein
the emitter electrode is in contact with the first emitter portion and is not in contact with the second emitter portion and the third emitter portion.

24. The semiconductor device according to claim 20, further comprising a trench contact portion provided from the upper surface of the semiconductor substrate to a position lower than that of an upper end of the base region and formed of a conductive material, wherein
the first emitter portion is in contact with the trench contact portion, and
the second emitter portion and the third emitter portion are not in contact with the trench contact portion.

25. The semiconductor device according to claim 24, further comprising:
a first high concentration region of a second conductivity type provided between the trench contact portion, and the second emitter portion and the third emitter portion and having a higher doping concentration than the base region; and
a second high concentration region of the second conductivity type provided in contact with a lower end of the trench contact portion and having a higher doping concentration than the base region, wherein
the first high concentration region has a lower doping concentration than the second high concentration region.

26. The semiconductor device according to claim 24, further comprising:
a contact dielectric film provided between the trench contact portion, and the second emitter portion and the third emitter portion; and
a high concentration region of a second conductivity type provided in contact with a lower end of the trench contact portion and having a higher doping concentration than the base region.
